(19) United States
(12) Patent Application Publication
(10) Pub. No.: US 2026/0016126 A1
(43) Pub. Date: Jan. 15, 2026

(54) OXIDANT GAS OR OXIDANT VAPOR GENERATION AND DELIVERY SYSTEMS AND METHODS

(71) Applicant: RASIRC, Inc., San Diego, CA (US)

(72) Inventors: Daniel Kazuma-Toh Hazen, San Diego, CA (US); Russell J. Holmes, San Diego, CA (US); Edward Heinlein, Ramona, CA (US); Adrian Alvarez, Ramona, CA (US); Joshua Garretson, San Diego, CA (US); Jeffrey J. Spiegelman, San Diego, CA (US)

(73) Assignee: RASIRC, Inc., San Diego, CA (US)

(21) Appl. No.: 19/254,848

(22) Filed: Jun. 30, 2025

Related U.S. Application Data
(60) Provisional application No. 63/670,576, filed on Jul. 12, 2024.
(60) Provisional application No. 63/687,989, filed on Aug. 28, 2024.

(51) Int. Cl. F17D 1/04; C22C 16/00; F16L 53/30; F17D 1/065; H01L 21/67

(52) U.S. Cl. CPC F17D 1/04; C22C 16/00; F16L 53/30; F17D 1/065; H01L 21/67017

(57) ABSTRACT

The techniques described herein relate to a method for delivering a gas including: forming a gas stream including an oxidant gas or oxidant vapor using an oxidant gas or oxidant vapor source of a system; transporting the gas stream from the oxidant gas or oxidant vapor source to another location of the system using a metal conduit; and heating the metal conduit using a heating apparatus coupled to the metal conduit. The metal conduit can include a metal alloy, wherein at least 90% of the metal alloy is: zirconium; hafnium; tantalum; a combination of zirconium and hafnium; a combination of zirconium and tantalum; a combination of hafnium and tantalum; or a combination of zirconium, hafnium, and tantalum. A gas or vapor delivery system can include an oxidant gas or oxidant vapor source; a metal conduit including the metal alloy; and a heating apparatus coupled to the metal conduit.

### RELATED APPLICATIONS

This application claims priority to U.S. Provisional Application No. 63/687,989 filed on Aug. 28, 2024 and also claims priority to U.S. Provisional Application No. 63/670,576 filed on Jul. 12, 2024; which are hereby incorporated by reference in full.

### BACKGROUND

Oxidants are used in many applications including combustion, sterilization, cleaning, and in chemical reactions involving oxidation-reduction processes. Oxidant gases or vapors can include hydrogen peroxide (H₂O₂), ozone (O₃), oxygen (O₂), hypochlorous acid (HOCl), nitric acid (HNO₃), nitrous oxide (N₂O), and nitrogen dioxide/dinitrogen tetroxide (NO₂/N₂O₄). These gases or vapors can be difficult to store, transport, and handle due to their reactive and corrosive properties.

For example, high concentration (>1000 ppm) hydrogen peroxide gas has applications as a redox reactant in the semiconductor industry. Delivery of the gas is challenging for a variety of reasons. Either high temperature (<120° C.), vacuum, or both, must be employed to reach high concentrations of H₂O₂ in the gas phase due to its low vapor pressure. Increasing the temperature also increases the spontaneous decomposition rate of H₂O₂ into H₂O and O₂. Both O₂ and H₂O have higher vapor pressure than H₂O₂ leading to diminished H₂O₂ concentration even when present in relatively small amounts. Thus, minimizing the non-spontaneous decomposition of H₂O₂ is paramount. For example, non-spontaneous decomposition of H₂O₂ can occur upon contact with the interior of a metal pipe. If the rate of decomposition is high, extreme internal pressure can develop due to the volume of O₂ generated.

As semiconductor manufacturing advances to smaller features, particle contamination mitigation has increased in importance. Materials in gas delivery systems should not generate or shed particles. Concentrated oxidant gases or vapors, such as hydrogen peroxide, under gas delivery conditions are exceptional at corroding materials. Generally, as materials corrode, they become more likely to generate large numbers of particles.

### SUMMARY

In some aspects, the techniques described herein relate to a method for delivering a gas including: forming a gas stream including an oxidant gas or oxidant vapor using an oxidant gas or oxidant vapor source of a system; transporting the gas stream from the oxidant gas or oxidant vapor source to another location of the system using a metal conduit, wherein the metal conduit includes a metal alloy, wherein at least 90% of the metal alloy is: zirconium; hafnium; tantalum; a combination of zirconium and hafnium; a combination of zirconium and tantalum; a combination of hafnium and tantalum; or a combination of zirconium, hafnium, and tantalum; and heating the metal conduit using a heating apparatus coupled to the metal conduit.

In some aspects, the techniques described herein relate to a gas or vapor delivery system including: an oxidant gas or oxidant vapor source including an outlet configured to output a gas stream including an oxidant gas or oxidant vapor; a metal conduit coupled to the oxidant gas or oxidant vapor source, the metal conduit including a metal alloy, wherein at least 90% of the metal alloy is: zirconium; hafnium; tantalum; a combination of zirconium and hafnium; a combination of zirconium and tantalum; a combination of hafnium and tantalum; or a combination of zirconium, hafnium, and tantalum; and a heating apparatus coupled to the metal conduit configured to heat the metal conduit.

### BRIEF DESCRIPTION OF THE DRAWINGS

FIG. 1A shows a simplified schematic of a system for vapor hydrogen peroxide generation and delivery, in accordance with some examples.

FIG. 1B is an example of a conduit that is made from the metal alloy, which is Zr 702 in this case.

FIGS. 1C-1D show a schematic of a face seal gland that can be made from the metal alloy, in accordance with some examples.

FIGS. 1E-1G show schematics and an image of a component of a hydrogen peroxide source, which is a bulkhead fitting between the head space of the hydrogen peroxide source and an outlet of the source, that can be made from the metal alloy, in accordance with some examples.

FIG. 1H shows a schematic a hydrogen peroxide source, in accordance with some examples.

FIG. 2 is a flowchart of a method vapor hydrogen peroxide delivery, in accordance with some examples.

FIG. 3 is a flowchart of a method for vapor hydrogen peroxide generation and delivery, in accordance with some examples.

FIG. 4 shows a graph of density changes in H₂O₂ solutions that contained the 316L steel and Zr 702 zirconium alloy samples.

FIG. 5 shows an example composition of a zirconium alloy (Zr 702).

FIG. 6A shows the trace metals results from samples of the H₂O₂ solution exposed to each of the 316L materials.

FIGS. 6B and 6C show Latimer diagrams for chromium and oxygen at pH 0.

FIG. 6D shows data from inductively coupled plasma mass spectrometry (ICP-MS) trace metals analysis of solutions that were used to test a batch of 316L stainless steel pieces.

FIG. 6E shows trace metals data from two H₂O₂ samples that were exposed to zirconium alloys (Zr 702).

FIGS. 7A and 7B show experimental setups used to evaluate the 316L steel and the Zr 702 zirconium alloy.

FIGS. 8A-8B show results of particle counts from 316L stainless steel before and after exposure to H₂O₂ condensate.

FIGS. 9A-9B show results of particle counts from the Zr 702 alloy before and after exposure to H₂O₂ condensate.

FIG. 10A shows a schematic of the experimental setup used to expose stainless steel (SS) and Zr alloy samples to humidified ozone.

FIG. 10B shows photographs of the SS sample after the 75 hours of exposure to ozone, and the filter paper which shows a fine, dark grey powder.

FIG. 10C shows photographs of the inlet (left) and outlet (right) sides of the Zr alloy sample tubing after exposure to ozone.

FIGS. 11A-11B show results of particle counts for the Zr alloy sample after exposure to ozone.

### DETAILED DESCRIPTION

The present disclosure relates generally to oxidant gas or oxidant vapor (e.g., hydrogen peroxide or ozone) generation and delivery systems and methods including metal alloys that limit an amount of decomposition of the oxidant gas or oxidant vapor, limit the generation of particles formed from the metal alloy when exposed to the oxidant gas or oxidant vapor, or both. The oxidant gases or oxidant vapors described herein can include any oxidant gases or oxidant vapors, such as but not limited to, hydrogen peroxide (H₂O₂), ozone (O₃), oxygen (O₂), hypochlorous acid (HOCl), nitric acid (HNO₃), nitrous oxide (N₂O), and nitrogen dioxide/dinitrogen tetroxide (NO₂/N₂O₄).

The systems and methods for oxidant gas or oxidant vapor generation and delivery described herein can include providing oxidant from an oxidant source to a location in the system using an oxidant delivery system. In some cases, the oxidant sources described herein are capable of delivering controlled and consistent quantities of oxidant gas or oxidant vapor (e.g., hydrogen peroxide or ozone), with a concentration of oxidant gas or oxidant vapor (optionally in a carrier gas) that is substantially stable over time. The oxidant source can include a housing and other source components made from the metal alloy, and the oxidant delivery system can include delivery components made from the metal alloy.

The metal alloy of the systems and methods for oxidant gas or oxidant vapor generation and delivery described herein can include, for example, zirconium (Zr), zirconium alloys with a high Zr content (e.g., Zr 702), hafnium (Hf), hafnium alloys with a high Hf content, tantalum (Ta), and tantalum alloys with a high Ta content. In some cases, the source or delivery components can be made from a solid, porous, and/or sintered metal alloy. For example, the metal alloy can include compositions wherein the percentage by mass of Zr, Hf, or Ta, is greater than 50%, greater than 80%, greater than 90%, greater than 95%, or greater than 99%. In some cases, the metal alloy can include compositions wherein a combined percentage by mass of one or more of: Zr, Hf, and Ta, is greater than 50%, greater than 80, greater than 90%, greater than 95%, or greater than 99%. In some cases, the metal alloy can include a composition wherein a combined amount of Zr and Hf, or a combined amount of Zr and Ta, is greater than 50% by mass, greater than 80% by mass, greater than 90% by mass, greater than 95% by mass, or greater than 99% by mass. In some cases, the metal alloy can include a combined composition of Zr and Hf greater than 99% by mass and less than 5% by mass Hf.

The systems and methods for oxidant gas or oxidant vapor generation and delivery described herein can include a metal alloy (e.g., a zirconium alloy, or Zr 702) for use as tubing, valves, and other miscellaneous high purity gas delivery components of high concentration oxidant gas (e.g., greater than 1000 ppmv). The metal alloy limits an amount of decomposition of the oxidant gas or oxidant vapor, limits the generation of particles formed from the metal alloy when exposed to the oxidant gas or oxidant vapor, or both.

The systems and methods for oxidant gas or oxidant vapor generation and delivery described herein can be used in any applications where combustion, sterilization, cleaning, or chemical reactions involving oxidation-reduction processes are needed. For example, semiconductor processing uses oxidants, such as hydrogen peroxide and ozone, for cleaning, etching, and as precursors for film growth. In another example, sterilization systems use oxidants, such as ozone, to clean surfaces of materials and objects. Some advantages of using the systems and methods described herein, including the metal alloy (e.g., a zirconium alloy, or Zr 702), are improved performance, uptime and yield of a process downstream from the oxidant gas or oxidant vapor generation and delivery system. For example, a semiconductor process using the oxidant gas or oxidant vapor as a process gas or process vapor could benefit from improved performance of fabricated semiconductor films or devices, and improved uptime and yield for the process.

Most metals and alloys form a layer of oxidized material when exposed to air. Under certain conditions, a continuous layer can form and prevent or limit oxidation of the metal underneath. Processes in which metal is purposely exposed to conditions to generate a protective oxide layer are referred to as passivation. Passivation typically works best on a clean smooth metal surface, since surface contamination, such as oils or grease, can prevent the passive layer from being continuous. Additionally, it can be difficult to form a defect-free (e.g., pinhole-free) passivation layer on a rough metal surface due to the presence of metal peaks and valleys.

The metal alloy (e.g., a zirconium alloy, or Zr 702) can be passivated by controlled exposure to oxidizing and/or reducing agents. Acids can be used to remove free metals, and oxidizing agents can grow the oxide layer. Pickling and polishing methods can also be used to smooth the metal alloy surface. For example, a pickling process using acids like hydrochloric (HCl) and sulfuric (H₂SO₄) can be used to remove impurities and oxides from the metal surface. After the pickling process, a uniform passive layer can be formed on the metal alloy surface. Electropolishing (EP) can also be used to smooth the surface of the metal alloy before passivation, by removing metal from the surface beginning at the sharpest points in some cases. Performing a passivation process after electropolishing can enable the growth of a thicker passive layer, which can help cover surface defects like inclusions and grain boundaries.

In some cases, a surface of the metal alloy in the systems and methods described herein is passivated. For example, a surface of the metal alloy can be passivated by cleaning the surface and forming an oxide on the surface. The surface can be cleaned, for example, by washing in cleanroom grade isopropyl alcohol (IPA), followed by ultrasonic cleaning in a cleaning solution (such as CITRAJET™) at elevated temperature. In some cases, the oxide can be formed on the surface by exposing the surface to steam or high temperature air or oxygen gas mixtures. Alternatively or additionally, a surface of a metal oxide can be passivated by exposing the surface to a liquid solution. In different cases, after passivation, the passivation layer on the metal surface can be from a single monolayer to over a micron in thickness. For example, the passivation layer can be a relatively thick film (e.g., with thickness greater than a micron), a relatively thin film (e.g., with a thickness less than 10 nm, or less than 100 nm, or less than a micron), or a single monolayer of atoms. In some cases, the passivation layer is an oxide layer formed on the surface of the material. The metal alloys (e.g., zirconium alloys, and Zr 702) can be passivated using sulfuric acid (H₂SO₄). In other cases, alternative passivation procedures using combinations of HNO₃, hydrofluoric acid (HF), H₂SO₄, and H₂O₂ may be used to generate passivation layers on the metal alloys (e.g., zirconium alloys, and Zr 702).

In some cases, different metal alloys can be used for one or more components within the systems and methods described herein. The one or more components can include metal alloys with different compositions of one or more of the following: zirconium, zirconium alloys with a high Zr content (e.g., Zr 702), hafnium, hafnium alloys with a high Hf content, tantalum, tantalum alloys with a high Ta content, and alloys with high Zr, Hf, and/or Ta content. For example, a first component (e.g., a conduit) of the oxidant (e.g., hydrogen peroxide or ozone) source or the gas delivery system can be made from a zirconium alloy, hafnium alloy, or a tantalum alloy with a first composition, and a second component (e.g., a housing) of the oxidant source or the gas delivery system can be made from a zirconium alloy, hafnium alloy, or a tantalum alloy with a second composition. The first and second compositions can include, for example, different amounts of Zr, Hf, Ta, and a small amount (e.g., less than 1%) of other elements (e.g., Fe, Cr, H, N, C, O, etc.). In some cases, two or more components of the hydrogen peroxide source or the gas delivery system can be made from a first metal alloy, and one or more other components can include a second metal alloy, for example, with a different amount of Zr, Hf, and/or Ta. In some cases, components in the oxidant source or the gas delivery system can be made from multiple metal alloys with multiple different compositions (e.g., 3, or 5, or 10, or more than 10 different metal alloys), where each composition includes, for example, a different amount of Zr, Hf, and/or Ta.

In some cases, the components of the systems and methods described herein can use metal alloys (e.g., zirconium alloys) that are unpassivated, or have not been cleaned and/or passivated.

In some cases, the housing and other source components of the oxidant source, and the delivery components of the oxidant delivery system, can include a coating made from the metal alloy. The metal alloy coating can be chemically or physically deposited, and can include, for example, zirconium, zirconium alloys with a high Zr content (e.g., Zr 702, or alloys with greater than 90% Zr, greater than 99% Zr, or greater than 99% Zr and Hf combined, and less than 5% Hf), hafnium zirconium alloys with a high Hf content, tantalum, and tantalum alloys with a high Ta content.

Due to the challenges described above, materials used in oxidant generation and delivery systems must be able to withstand at least moderate pressure increases. Additionally, it is advantageous that the materials are thermally conductive to prevent localized cold spots which can cause the gas to condense, which can affect concentration and flow stability. Semiconductor manufacturing requires exceptionally high leak rate integrity, on the order of 1×10⁻⁹ atm·cc/sec. Therefore, it is advantageous for the materials to form and maintain seals to this degree. Overall, it is advantageous for materials for high concentration oxidant (e.g., hydrogen peroxide) gas delivery to 1) be able to withstand high temperature, vacuum conditions, and pressure conditions, 2) have high thermal conductivity, 3) have low leak rate seals, 4) have acceptable resistance to corrosion, and 5) have acceptable reactivity (decomposition rates) with the oxidant (e.g., H₂O₂).

Hydrogen peroxide (H₂O₂) complicates the corrosion of metals. If transition metal ions are present in sufficient quantity, the oxidation potential of H₂O₂ is increased. Iron was the first metal identified to have this property by H. Fenton, leading to this mixture being named Fenton's Reagent. Fenton's reagent, or Fenton-like reagents in the case of non-iron metals, can continuously decompose H₂O₂ to generate OH⁻ and ^{·}OH radical groups. This reaction can occur at low pHs (3-5). The pH of H₂O₂ is relatively low, and ranges from 4.5 to 4.9 between 50-90 wt. % at 25° C. Furthermore, as temperature increases, pH is expected to drop, and the decomposition rate of H₂O₂ can increase.

Conventionally, applications often avoid using concentrated H₂O₂ gas delivery. For example, lower concentration hydrogen peroxide (e.g., below about 30 wt %) is typically used in the semiconductor industry. Other industries that use high concentrations of hydrogen peroxide like aerospace/rocketry, generally use it in a liquid phase and do not deliver high concentration H₂O₂ gas or vapor to an end use at high temperatures. These applications, such as aerospace/rocketry, are also less concerned about submicron particles that may be generated during use. Storage conditions for high concentrations of hydrogen peroxide also typically include lower temperatures.

Conventional systems for delivering gases or vapors typically use materials such as aluminum, plastics, stainless steel, and coated materials.

Some source and delivery components of the oxidant generation and delivery systems and methods described herein can use materials such as aluminum, plastics, stainless steel, and coated materials. However, in some cases, it can be advantageous to replace a source or delivery component made of these materials with a component made from the metal alloy (e.g., a zirconium alloy). For example, components that are in regular contact with oxidant gas or oxidant vapor, or components where the oxidant gas or oxidant vapor (e.g., hydrogen peroxide) tends to condense, can benefit from using the metal alloy (e.g., a zirconium alloy).

For example, aluminum alloys, polytetrafluoroethylene (PTFE), and perfluoroalkoxy (PFA) can be used for some components. However, these materials may be too soft from a durability/sealing standpoint to be used for some oxidant gas or oxidant vapor source or delivery components. Additionally, PFA is moisture permeable, which can limit its use for some oxidant gas or oxidant vapor source or delivery components.

In another example, high chromium metals, like stainless steel alloys, can be used for some components of the oxidant gas or oxidant vapor systems and methods described herein. However, the passivated layer of these materials can dissolve over time leaving a reactive surface, which can limit its use for some oxidant gas or oxidant vapor source or delivery components.

In another example, high nickel metals, like Hastelloy, can be used for some components of the oxidant gas or oxidant vapor systems and methods described herein. However, these materials tend to corrode under conditions required for oxidant gas or oxidant vapor (e.g., concentrated H₂O₂) delivery, which can limit its use for some source or delivery components.

In another example, coatings and coated materials can be used for some components of the oxidant gas or oxidant vapor systems and methods described herein. However, these materials can fail because the oxidant gas or oxidant vapor (e.g., H₂O₂) can diffuse through or under the coating before decomposing. In the case of hydrogen peroxide, this can lead to the generation of oxygen gas and liquid water which can delaminate or separate the coating from the surface. If also exposed to vacuum, the coating may completely separate from the surface. If the coating includes the metal alloy (e.g., a zirconium alloy) and is sufficiently dense and thick, then the coating may provide a surface with acceptable resistance to corrosion, and acceptable reactivity (decomposition rates) with the oxidant gas or oxidant vapor (e.g., H₂O₂).

The metal alloys can include alloys of zirconium, hafnium, and/or tantalum. In some cases, the amount of zirconium is higher than the amount of hafnium and/or tantalum in the alloy. High zirconium content alloys can be advantageous, for example, because zirconium is less expensive than hafnium or tantalum, and high zirconium alloys provide acceptable resistance to corrosion, and have acceptable reactivity (decomposition rates) with oxidants (e.g., H₂O₂).

In some cases, the systems and methods for oxidant gas or oxidant vapor generation and delivery described herein can include a metal alloy (e.g., a zirconium alloy, or Zr 702) in regions wherein the oxidant gas or oxidant vapor condenses and reevaporates. The metal alloy (e.g., a zirconium alloy, or Zr 702) can be resistant to corrosion in these regions from the oxidant gas, vapor, or condensate, can limit the number of particles generated in these regions, and/or can limit the decomposition of the oxidant in these regions.

For example, the systems and methods for vapor hydrogen peroxide generation and delivery described herein can include a metal alloy (e.g., a zirconium alloy, or Zr 702) that allows for delivery of hot concentrated H₂O₂ gas that might contain water vapor and/or a carrier gas. The metal alloy can prevent or limit H₂O₂ decomposition and particle generation during exposure to H₂O₂ gas or condensate. The metal alloy can cause less H₂O₂ decomposition and particle generation during exposure to H₂O₂ gas or condensate than other metals such as stainless steel (e.g., 304 and 316L), aluminum, ferrous steel, or titanium. For example, stainless steel (316L) can cause decomposition of H₂O₂ at elevated temperatures. The 316L steel can become slowly passivated over time, but even passivated steel was found to cause H₂O₂ decomposition.

In another example, the oxidant can be a liquid at room temperature, and the systems and methods for oxidant gas or oxidant vapor generation and delivery described herein can include a metal alloy (e.g., a zirconium alloy, or Zr 702) that is heated. In such cases, one or more regions can include a cold spot where the oxidant gas or oxidant vapor condenses, and these one or more regions can include the metal alloy to limit the number of particles generated in these regions, and/or limit the decomposition of the oxidant in these regions.

In another example, the systems and methods for oxidant gas or oxidant vapor generation and delivery described herein can include a metal alloy (e.g., a zirconium alloy, or Zr 702) and include a cold spot in an area where the gas or vapor expands (e.g., at an input from a tube to a chamber, or where an inner diameter of a tube increases) due to the Joule-Thomson effect (where a gas cools down when it expands from a high-pressure region to a low-pressure region). In such cases, these one or more regions can include the metal alloy to limit the number of particles generated in these regions, and/or limit the decomposition of the oxidant in these regions.

In some cases, filters can be used to capture particles after being generated. However, in some cases filters with sufficient pore sizes cause oxidant gas or oxidant vapor (e.g., H₂O₂) decomposition and large pressure drops. In cases where the oxidant gas or oxidant vapor is a condensable gas (e.g., O₃ or H₂O₂), any pressure drop can also lead to condensation and cooling.

In some cases, the systems and methods for vapor hydrogen peroxide generation and delivery described herein can include a metal alloy (e.g., a zirconium alloy, or Zr 702) in a location that is more likely to experience corrosion. For example, localized areas where hot oxidant gas or oxidant vapor (e.g., hot H₂O₂ gas, optionally mixed with H₂O gas) repeatedly condenses into liquid and re-vaporizes, can experience higher rates of corrosion leading to particle generation at the site of corrosion. In some cases, a metal can have a clean and shiny appearance after exposure to an oxidant gas, vapor, or condensate; however, it can still generate a significant amount of particles (e.g., under condensing conditions).

In some cases, the systems and methods for oxidant gas or oxidant vapor generation and delivery described herein can include a metal alloy (e.g., a zirconium alloy, or Zr 702) and can deliver oxidant gas or oxidant vapor (e.g., heated and/or concentrated H₂O₂ vapor, or O₃) for high purity applications, such as semiconductor and microelectronics manufacturing. In some cases, the metal alloys (e.g., substantially zirconium, hafnium or tantalum) form metal fluid pathways of a gas delivery system, through which the hydrogen peroxide travels after it is generated. The gas delivery system can include components such as conduits, fittings, valves, sensors, and others, as described herein.

In some cases, the systems and methods for vapor hydrogen peroxide generation and delivery described herein can include a metal alloy (e.g., a zirconium alloy, or Zr 702) where the metal alloy has one or more of the following characteristics: does not decompose or limits the decomposition of the oxidant (e.g., H₂O₂); does not form particles or limits the formation of particles when exposed to oxidant vapor or condensate; does not corrode or experiences limited corrosion when exposed to oxidant vapor or condensate. The metal alloy can be included in an oxidant source (e.g., with a metal housing or vaporizer), or in gas delivery components such as heat exchangers, heaters, fittings, valves, flowmeters, filters, pressure controllers, regulators, and fluid sensors.

In some cases, the systems and methods for oxidant gas or oxidant vapor generation and delivery described herein can include a metal alloy (e.g., a zirconium alloy, or Zr 702) that is heated. For example, a component can be heated to prevent or limit condensation. However, condensation can still occur in heated components, for example, due to environmental conditions, change in tubing size, direction, wall thickness, or thermal contacts and supports. In addition, Joule-Thompson effects of cooling through an orifice can occur when gas is passing though valves, regulators and flow meters. Using the metal alloy can be advantageous, to enable the system to deliver heated concentrated oxidant (e.g., H₂O₂) gas or vapor with no (or a small amount of) particles and minimal decomposition, even when there is condensation within the gas path.

In some cases, the metal alloy limits generation of particles formed from the metal alloy when exposed to liquid, vapor, or condensed and evaporated oxidant (e.g., hydrogen peroxide). For example, the metal alloy can form no particles or substantially no particles when exposed to liquid, vapor, or condensate oxidant. In some cases, the metal alloy generates fewer particles than stainless steel, aluminum, ferrous steel, or titanium when exposed to liquid, vapor, or condensed and evaporated oxidant (e.g., hydrogen peroxide). For example, the metal alloy can generate 2 times, 10 times, or 100 times fewer particles than stainless steel, aluminum, ferrous steel, or titanium when exposed to liquid, vapor, or condensed and evaporated oxidant.

In some cases, the metal alloy limits an amount of decomposition of the oxidant gas or oxidant vapor (e.g., hydrogen peroxide), at room temperature or at elevated temperatures. For example, the metal alloy can decompose substantially none of the oxidant, or less than 1% of the oxidant over hours or days (e.g., 6 hours, 24 hours, 1 day, or 2 days, or 9 days, or more than 9 days) at a temperature of approximately 80° C. In some cases, the metal alloy decomposes the oxidant gas or oxidant vapor less than stainless steel, aluminum, ferrous steel, or titanium. For example, the metal alloy can decompose the oxidant gas or oxidant vapor 10% less, 20% less, 30% less, 50% less, 80% less, or 90% less than stainless steel, aluminum, ferrous steel, or titanium.

In some cases, the metal alloy does not corrode when exposed to liquid, vapor, or condensed and evaporated oxidant (e.g., hydrogen peroxide). In some cases, the metal alloy corrodes less than stainless steel, aluminum, ferrous steel, or titanium does when exposed to condensed and evaporated vapor oxidant. For example, the metal alloy can corrode 10% less, 20% less, 30% less, 50% less, 80% less, or 90% less than stainless steel, aluminum, ferrous steel, or titanium when exposed to liquid, vapor, or condensed and evaporated oxidant.

In some cases, the systems and methods for oxidant gas or oxidant vapor (e.g., hydrogen peroxide) generation and delivery described herein including the metal alloy (e.g., a zirconium alloy, or Zr 702) can be used to deliver oxidant gas or oxidant vapor to a semiconductor process that uses a semiconductor wafer. In such cases, the metal alloy can limit particle generation in the system such that there are no particles or a small number of particles on the wafer. For example, a delivery system for H₂O₂ or ozone can include Zr-based components, and can deliver gas or vapor H₂O₂ or ozone from a source to semiconductor process equipment. A wafer (e.g., Silicon, Germanium, Group III-V materials, Sapphire, glass, silicon carbide, other structures, such as thin film substrates) can be processed using the semiconductor process equipment, and the wafer can be substantially free of metal particles from the oxidant gas or oxidant vapor generation and delivery system.

For example, the systems and methods described herein including the metal alloy (e.g., a zirconium alloy, or Zr 702) can be used to grow an oxide film on a wafer using an ALD or CVD process that is free of metal particles from the oxidant gas or oxidant vapor generation and delivery system.

In another example, systems and methods for oxidant gas or oxidant vapor generation and delivery described herein including the metal alloy (e.g., a zirconium alloy, or Zr 702) can be used to modify the surface of a material by exposing the material to the vapor oxid oxidant gas or oxidant vapor ant (e.g., hydrogen peroxide, optionally at elevated temperature. Similar to the above examples, the oxidant gas or oxidant vapor can be delivered using the systems and methods described herein and advantageously produce modified surfaces that are substantially free of metal particles from the oxidant gas or oxidant vapor generation and delivery system.

In another example, systems and methods for oxidant gas or oxidant vapor (e.g., H₂O₂) generation and delivery described herein including the metal alloy (e.g., a zirconium alloy, or Zr 702) can be used to oxidize a silazane molecule on a wafer. Silazane molecules are analogous to siloxanes, with —NR—(R=alkyl, aryl) replacing —O—. Similar to the above examples, the oxidant gas or oxidant vapor can be delivered using the systems and methods described herein and advantageously react with the silazane molecule, and the wafer can be substantially free of metal particles from the oxidant gas or oxidant vapor generation and delivery system. This could be used, for example, in a semiconductor manufacturing gap fill cure process, where the silazane molecule could be in a solution coated material, or an ALD or CVD deposited layer of silicon atoms, that is converted to a silicon oxide layer using vapor hydrogen peroxide.

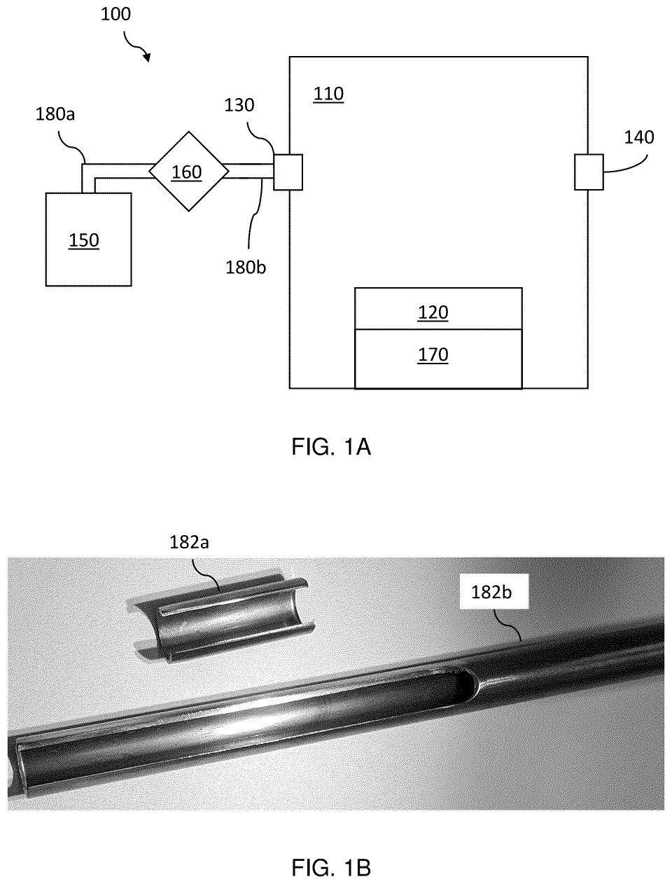

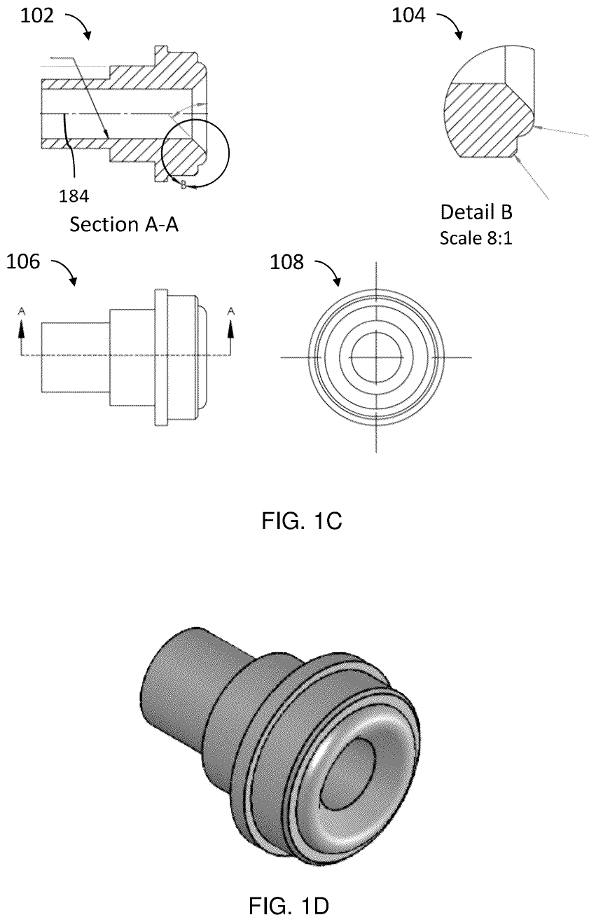

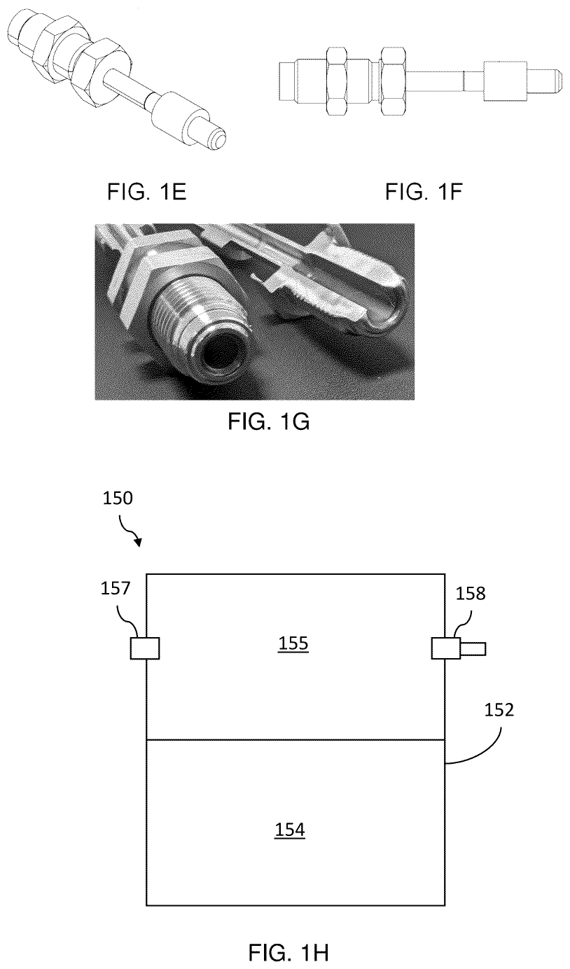

FIG. 1A shows a simplified schematic of an example of a system 100 for oxidant gas or oxidant vapor (e.g., hydrogen peroxide or ozone) generation and delivery, in accordance with some examples. The system 100 includes a chamber 110 of a piece of equipment, with a material 120 (e.g., a wafer, a substrate, or a polymeric material) inside the chamber 110, an inlet 130 to the chamber 110 for providing oxidant gas or oxidant vapor to the chamber 110, and an outlet 140 from the chamber 110 for removing species from the chamber 110. In some cases, an oxidant plasma (e.g., a hydrogen peroxide plasma, or an oxygen plasma) can be provided to chamber 110 through inlet 130. An optional heater 170 can be used to control the temperature of the material 120 (e.g., a bulk material, substrate, layered structure, etc.). Some examples of chamber 110 are a vacuum chamber, an atomic layer deposition reactor chamber, a sterilization chamber, an etch or a selective etch reactor chamber, an ashing chamber, a chemical vapor deposition chamber, a surface cleaning reactor chamber, a passivating chamber, a photolithography process chamber, a plasma chamber, a microwave plasma chamber, a radio frequency plasma chamber, a coating chamber, a powder coating chamber, an oxidation process chamber, and a material curing chamber.

Oxidant gas or oxidant vapor source 150 can output oxidant gas or oxidant vapor, such as hydrogen peroxide (H₂O₂), ozone (O₃), oxygen (O₂), hypochlorous acid (HOCl), nitric acid (HNO₃), nitrous oxide (N₂O), and nitrogen dioxide/dinitrogen tetroxide (NO₂/N₂O₄), into conduit 180a. For example, oxidant gas or oxidant vapor source 150 can be a hydrogen peroxide source that can output vapor hydrogen peroxide (e.g., gaseous hydrogen peroxide, hydrogen peroxide vapor, substantially anhydrous hydrogen peroxide, or a mixed gas stream containing hydrogen peroxide). In various examples, oxidant gas or oxidant vapor source 150 can include one or more of an ozone generator, an oxygen source, a hypochlorous acid source, a nitric acid source, a nitrous oxide source, and a nitrogen dioxide/dinitrogen tetroxide source. The oxidant gas or oxidant vapor source can include a housing and other source components made from the metal alloy, and the oxidant gas or oxidant vapor system can include delivery components made from or containing the metal alloy. In some cases, a surface of the metal alloy in the oxidant gas or oxidant vapor source or other component of the system is passivated.

Gas delivery system 160 contains gas delivery components, which can include, but are not limited to, one or more of conduits, heat exchangers, heaters, fittings, valves, flowmeters, filters, pressure controllers, regulators, and fluid sensors. In some cases, one or more components of the gas delivery system 160 are heated.

A carrier gas (e.g., argon, or other inert gas) can flow through oxidant gas or oxidant vapor source 150, or a vacuum can be used (e.g., using a vacuum pump coupled to chamber outlet 140), to deliver the oxidant gas or oxidant vapor from the oxidant gas or oxidant vapor source 150 to chamber 110. Excess carrier gas and other processing byproducts can be removed from chamber 110 using outlet 140. The oxidant gas or oxidant vapor source 150 and gas delivery system 160 can provide a controlled oxidant gas or oxidant vapor (e.g., a hydrogen peroxide or ozone) to material 120 within the chamber 110 for a controlled duration of time, and optionally at a controlled temperature. For example, oxidant gas or oxidant vapor source 150 can provide a concentration of hydrogen peroxide vapor to chamber 110 that is substantially stable over time. In some cases, the oxidant gas or oxidant vapor source 150 and gas delivery system 160 can provide a controlled oxidant plasma (e.g., a hydrogen peroxide plasma) to material 120 within the chamber 110 for a controlled duration of time, and optionally at a controlled temperature.

The components of the oxidant gas or oxidant vapor source 150 and the gas delivery system 160 that come into contact with the oxidant gas or oxidant vapor can be made from the metal alloy (e.g., a zirconium alloy, or Zr 702), and thereby enable the oxidant gas or oxidant vapor entering chamber 110 to be substantially free of particles. Additionally, the decomposition of the oxidant gas or oxidant vapor in the oxidant gas or oxidant vapor source 150 and the gas delivery system 160 can be limited, as described herein.

In some cases, oxidant gas or oxidant vapor source 150 is coupled to gas delivery system 160 via conduit 180a to provide a substantially stable concentration of the oxidant gas or oxidant vapor to gas delivery system 160, and gas delivery system 160 is coupled to inlet 130 via conduit 180b to provide the oxidant gas or oxidant vapor (or optionally plasma containing the oxidant) to chamber 110. In some cases, the oxidant gas or oxidant vapor gas can be delivered from an ampoule (or other vessel or container) within oxidant gas or oxidant vapor source 150, and the ampoule or vessel can be made from the metal alloy (e.g., a zirconium alloy, or Zr 702). System 100 can also include some components that are not shown, for example, a vacuum pump can be coupled to outlet 140 of chamber 110 to enable a low pressure (or vacuum) environment in chamber 110. The gas delivery system 160 (and conduit 180b) can be used to transport the oxidant gas or oxidant vapor under low pressures, and therefore components of the gas delivery system 160 and the source 150 can also be held at low pressure or vacuum, in some examples. In such cases, the valves and gas control apparatuses in gas delivery system 160 can be used to control the pressure in the components of system 100. In some cases, an oxidant plasma can be formed from the oxidant gas or oxidant vapor output from the oxidant gas or oxidant vapor source 150. The plasma can then be provided to the chamber 110. Not to be limited by theory, an oxidant plasma (e.g., hydrogen peroxide plasma) can have a short lifetime at a pressure about 1 atmosphere, therefore low pressure environments within the system 100 can be advantageous.

In some cases, the gas delivery system 160 can be close to or integrated with oxidant gas or oxidant vapor source 150 or chamber 110. For example, conduit 180b can be short (e.g., less than 10 cm, or less than 1 cm) and inlet 130 can be close to the gas delivery system 160. In some examples of system 100, conduit 180b can be omitted and inlet 130 can directly couple the gas delivery system 160 to chamber 110.

In some cases, oxidant gas source 150 is a source of ozone, and the oxidant is ozone gas. The components of oxidant gas source 150 and other components of the system 100 can include metal alloys that limit an amount of decomposition of the ozone gas, limit the generation of particles formed from the metal alloy when exposed to the ozone gas, or both. In some cases, a mixture of ozone and another gas (e.g., oxygen) can be generated in the oxidant gas source 150, for example with a weight fraction of ozone from about 10% to about 50%, from about 10% to about 35%, about 20%, about 35%, or greater than 50%. The flow rate of gas through the system 100 or through oxidant gas source 150 is not particularly limited, and in some cases can be from 1 slm (standard liter per minute) to 100 slm, or from 5 slm to 20 slm, greater than 100 slm, or greater than 1000 slm in some cases.

For example, chamber 110 can be a sterilization chamber, and ozone can be delivered to the chamber 110 using the gas delivery system 160, and one or more components of the oxidant gas source 150 and gas delivery system 160 can include the metal alloy (e.g., a Zr alloy such as Zr 702). In such cases, material 120 can be an object for sterilization, and the object can optionally be heated to a temperature from about 100° C. to 1200° C., greater than about 100° C., or greater than about 1200° C. and exposed to the ozone for a duration from about 1 second to about 1 hour, greater than 1 min, or greater than 1 hour during the sterilization process.

In some cases, oxidant gas source 150 is a source of oxygen, and the oxidant is oxygen gas. The components of oxidant gas source 150 and other components of the system 100 can include metal alloys that limit an amount of decomposition of the oxygen gas, limit the generation of particles formed from the metal alloy when exposed to the oxygen gas, or both. In some cases, a mixture of oxygen and another gas (e.g., one or more inert carrier gases such as nitrogen or argon) can be generated or supplied by the oxidant gas source 150. For example, the gas mixture can have a weight fraction of oxygen from about 1% to about 99%, or greater than 99%. The flow rate of gas through the system 100 is also not particularly limited, and in some cases can be from 1 slm (standard liter per minute) to 100 slm, or from 5 slm to 20 slm, greater than 100 slm, or greater than 1000 slm in some cases.

For example, chamber 110 can be an oxidation chamber, and oxidant gas source 150 can be a source of oxygen. The oxygen can be delivered to the chamber 110 using the gas delivery system 160. In some cases, chamber 110 can be under vacuum, for example, from about 1e-3 Torr to about 1e-9 Torr, or from about 1e-6 Torr to about 1e-9 Torr. One or more components of the oxidant gas source 150 and gas delivery system 160 can include the metal alloy (e.g., a Zr alloy such as Zr 702). In such cases, material 120 can be an object for oxidation, and the object can optionally be heated to a temperature from about 100° C. to 1200° C., greater than about 100° C., or greater than about 1200° C. and exposed to the oxygen for a duration from about 1 second to about 1 hour, greater than 1 min, or greater than 1 hour during the oxidation process.

In some cases, oxidant vapor source 150 is a source of nitric acid, and the oxidant is nitric acid vapor. For example, oxidant vapor source 150 can include a bubbler containing an aqueous solution of nitric acid and water. The components of oxidant vapor source 150 and other components of the system 100 can include metal alloys that limit an amount of decomposition of the nitric acid vapor, limit the generation of particles formed from the metal alloy when exposed to the nitric acid vapor, or both. In some cases, a mixture of nitric acid vapor and another gas or vapor (e.g., water vapor, air, oxygen, or an inert carrier gas such as nitrogen) can be generated or supplied by the oxidant vapor source 150. For example, the aqueous solution can have a weight fraction of nitric acid from about 50 wt. % to about 80 wt. %, or greater than about 80 wt. %. The flow rate of gas and vapor through the system 100 is not particularly limited, and in some cases can be from about 100 mL/min to about 100 L/min, from about 100 mL/min to about 10 L/min, from about 1 L/min to about 10 L/min, or greater than 100 L/min.

For example, chamber 110 can be an oxidation chamber for a semiconductor process, and oxidant gas or oxidant vapor source 150 can be a source of nitric acid vapor. The nitric acid vapor can be delivered to the chamber 110 using the gas delivery system 160, and one or more components of the oxidant vapor source 150 and gas delivery system 160 can include the metal alloy (e.g., a Zr alloy such as Zr 702). For example, a material 120 can be a semiconductor wafer (e.g., silicon) that is heated in the chamber 110 and the nitric acid vapor can be delivered to chamber 110 to form an oxide on the material 120. In such cases, material 120 can be an object for oxidation, and the object can optionally be heated to a temperature from about 100° C. to 1200° C., greater than about 100° C., or greater than about 1200° C. and exposed to the nitric acid for a duration from about 1 second to about 1 hour, greater than 1 min, or greater than 1 hour during the oxidation process.

In some cases, oxidant vapor source 150 is a source of hypochlorous acid, and the oxidant is hypochlorous acid vapor. For example, oxidant vapor source 150 can include a bubbler containing an aqueous solution of hypochlorous acid and water. The components of oxidant vapor source 150 and other components of the system 100 can include metal alloys that limit an amount of decomposition of the hypochlorous acid vapor, limit the generation of particles formed from the metal alloy when exposed to the hypochlorous acid vapor, or both. In some cases, a mixture of hypochlorous acid vapor and another gas or vapor (e.g., water vapor, air, oxygen, or an inert carrier gas such as nitrogen) can be generated or supplied by the oxidant vapor source 150. For example, an aqueous solution of hypochlorous acid can be used in the oxidant vapor source 150 (e.g., a bubbler) that has from 50 ppm to 500 ppm of Cl, or greater than 50 ppm of Cl, or greater than 500 ppm Cl. The flow rate of gas through the system 100 is not particularly limited, and in some cases can be from about 100 mL/min to about 100 L/min, from about 100 mL/min to about 10 L/min, from about 1 L/min to about 10 L/min, or greater than 100 L/min.

For example, chamber 110 can be a sterilization chamber, and oxidant vapor source 150 can be a source of hypochlorous acid vapor. The hypochlorous acid vapor can be delivered to the chamber 110 using the gas delivery system 160, and one or more components of the oxidant vapor source 150 and gas delivery system 160 can include the metal alloy (e.g., a Zr alloy such as Zr 702). For example, a material 120 can be a piece of medical equipment, a biological sample, or other object to be sterilized, and the hypochlorous acid vapor can be delivered to chamber 110 to sterilize the material 120. In such cases, material 120 can be an object for sterilization, and the object can optionally be heated to a temperature from about 100° C. to 1200° C., greater than about 100° C., or greater than about 1200° C. and exposed to the hypochlorous acid for a duration from about 1 second to about 1 hour, greater than 1 min, or greater than 1 hour during the sterilization process.

In some cases, oxidant gas source 150 is a source of nitrogen dioxide and/or dinitrogen tetroxide (i.e., nitrogen dioxide, dinitrogen tetroxide, or nitrogen dioxide and dinitrogen tetroxide), and the oxidant is nitrogen dioxide and/or dinitrogen tetroxide gas. The components of oxidant gas source 150 and other components of the system 100 can include metal alloys that limit an amount of decomposition of the nitrogen dioxide and/or dinitrogen tetroxide gas, limit the generation of particles formed from the metal alloy when exposed to the nitrogen dioxide and/or dinitrogen tetroxide gas, or both. In some cases, a mixture of nitrogen dioxide and/or dinitrogen tetroxide and another gas (e.g., one or more inert carrier gases such as nitrogen or argon) can be generated or supplied by the oxidant gas source 150, for example with a weight fraction of nitrogen dioxide and/or dinitrogen tetroxide from about 100 ppm to about 1%, from about 100 ppm to about 1000 ppm, or greater than 1%. The flow rate of gas through the system 100 is not particularly limited, and in some cases can be from 1 slm (standard liter per minute) to 100 slm, or from 5 slm to 20 slm, greater than 100 slm, or greater than 1000 slm in some cases.

For example, chamber 110 can be an oxidation chamber, and oxidant gas source 150 can be a source of nitrogen dioxide and/or dinitrogen tetroxide. The nitrogen dioxide and/or dinitrogen tetroxide can be delivered to the chamber 110 using the gas delivery system 160. In some cases, chamber 110 can be under vacuum, for example, from 1e-6 Torr to 1e-9 Torr. One or more components of the oxidant gas source 150 and gas delivery system 160 can include the metal alloy (e.g., a Zr alloy such as Zr 702). In such cases, material 120 can be an object for oxidation, and the object can optionally be heated to a temperature from about 100° C. to 1200° C., greater than about 100° C., or greater than about 1200° C. and exposed to the nitrogen dioxide and/or dinitrogen tetroxide for a duration from about 1 second to about 1 hour, greater than 1 min, or greater than 1 hour during the oxidation process.

In some cases, the oxidant gas or oxidant vapor source 150 can be filled with high-quality hydrogen peroxide for generation of hydrogen peroxide vapor and delivery to chamber 110. In some cases, the liquid hydrogen peroxide solution in hydrogen peroxide source 150 is anhydrous or substantially anhydrous. In practice, it is difficult to remove all of the water from hydrogen peroxide, and in some cases, substantially anhydrous hydrogen peroxide contains less than 60%, less than 50%, less than 40%, less than 30%, less than 20%, less than 10%, less than 1%, less than 0.1%, less than 0.01%, or less than 0.001% water by weight. In some cases, hydrogen peroxide source 150 can be filled with mixed gases and/or vapors, which can contain hydrogen peroxide and other species, such as water. In some cases, the hydrogen peroxide in hydrogen peroxide source 150 is mixed with water, wherein the amount of water in the mixture (or mixed gas) by weight is from 10 ppm to 99%, or from 100 ppm to 75%, or from 100 ppm to 35%, or from 10 ppm to 1%, or from 1% to 99%, or from 30% to 99%, or from 30% to 75%, or is less than 10%, less than 2%, less than 0.5%, less than 1000 ppm, less than 100 ppm, less than 10 ppm. In some cases, a mixture output from hydrogen peroxide source 150 can include primarily hydrogen peroxide vapor. For example, a mixture output from hydrogen peroxide source 150 can include hydrogen peroxide vapor and a small concentration (e.g., less than 10%, or less than 1%, or less than 0.1%) of water and/or oxygen. In another example, a mixture output from hydrogen peroxide source 150 can include hydrogen peroxide vapor and other components (e.g., water, or a carrier gas) where the other components are present at higher concentrations (e.g., up to 60%, or even higher in the case of a mixture of hydrogen peroxide vapor and a carrier gas).

In some cases, hydrogen peroxide can be delivered from the oxidant gas or oxidant vapor source 150 to the chamber 110 using a carrier gas. The mixture of the hydrogen peroxide vapor and the carrier gas from the oxidant gas or oxidant vapor source 150 can comprise less than 10%, or less than 1% of oxygen by weight, or less than 1000 ppm, or less than 100 ppm of oxygen. In other cases, the carrier gas can contain an additional oxidant gas or oxidant vapor. For example, the carrier gas can be formed by combining an inert gas such as argon or nitrogen with oxygen, where a ratio of the oxygen flow rate to the inert gas flow rate is from 1:10 to 1:1, or about 1:4, or less than 1:4 (i.e., the flow rate of oxygen is less than 25% the flow rate of the inert gas).

For example, chamber 110 can be an oxidation chamber or a chamber for a surface modification process, and oxidant gas or oxidant vapor source 150 can be a source of hydrogen peroxide vapor. The hydrogen peroxide vapor can be transported to the chamber 110 using a carrier gas or vacuum as described herein, using the gas delivery system 160. In some cases, chamber 110 can be under vacuum, for example, from about 1e-3 Torr to about 1e-9 Torr, or from about 1e-6 Torr to about 1e-9 Torr. In other cases, a carrier gas with a flow rate from about 100 sccm to about 10,000 sccm, from about 100 sccm to about 1000 sccm, or greater than 1000 sccm, or greater than about 10,000 sccm can be used to transport the hydrogen peroxide. For example, the carrier gas can include an inert gas and oxygen with an overall flow rate from about 100 sccm to about 10,000 sccm, where the flow rate of the inert gas is from 1 to 10 times greater than the flow rate of the oxygen. One or more components of the oxidant gas source 150 and gas delivery system 160 can include the metal alloy (e.g., a Zr alloy such as Zr 702). In such cases, material 120 can be an object for oxidation or surface modification, and the object can optionally be heated to a temperature from about 100° C. to about 1200° C., from about 100° C. to about 500° C., from about 100° C. to about 300° C., greater than about 100° C., or greater than about 1200° C., and exposed to the hydrogen peroxide vapor, and the carrier gas if present, for a duration from about 1 second to about 1 hour, from about 10 seconds to about 10 min, greater than 1 min, or greater than 1 hour during the oxidation process.

In some examples, an oxidant vapor including hydrogen peroxide vapor is delivered to a location using vacuum or using a carrier gas (e.g., argon, or other inert gas). In some examples, the gas is substantially free of oxygen (e.g., contains less than 10%, less than 1%, less than 0.1%, less than 0.01%, or less than 0.001% oxygen by weight). In some examples, gas including the hydrogen peroxide vapor is anhydrous or substantially anhydrous (e.g., contains less than 10%, less than 1%, less than 0.1%, less than 0.01%, or less than 0.001% water by weight). In some examples, the gas contains less than 60%, less than 50%, less than 40%, less than 30%, less than 20%, less than 10%, less than 1%, less than 0.1%, less than 0.01%, or less than 0.001% water by weight, or from 1% to 60%, or from 1% to 20%, or from 0.001% to 1% water by weight. The carrier gas, when used, can be many different species such as noble gases (e.g., argon, helium, neon, krypton, etc.), nitrogen, compressed dry air (CDA), or hydrogen.

The ability to deliver a controlled and consistent concentration of hydrogen peroxide vapor to form the hydrogen peroxide plasma is difficult. Systems and methods to deliver hydrogen peroxide, particularly those capable of delivering a controlled and consistent concentration of hydrogen peroxide vapor, are further described in U.S. Pat. Nos. 8,282,708, 9,410,191, 9,545,585, 9,610,550, 10,363,497, and 11,634,816; U.S. Pat. Pub. Nos. US20200291517A1, and US20200393086A1; U.S. App. No. U.S. Ser. No. 18/472,551; and International Pub. Nos. WO2016/164380 and WO2017/027581, each of which is incorporated herein by reference in their entireties. Such systems and methods to deliver hydrogen peroxide can be used in the systems and methods described herein, for example, in oxidant gas or oxidant vapor source 150 in FIG. 1A. Some examples of systems and methods to deliver hydrogen peroxide are described herein.

In some examples, the systems and methods described herein include oxidant gas or oxidant vapor, such as hydrogen peroxide, sources configured to provide and maintain a concentration of oxidant gas or oxidant vapor in the gas mixture that is substantially stable over time (or is maintained at a substantially constant value or relatively constant value over time). The concentration (or volume fraction) of the oxidant gas or oxidant vapor (e.g., hydrogen peroxide) in the gas mixture can be substantially stable, for example, if the concentration is maintained to within 5%, or within 3%, or within 1% of the mean over an hour of gas mixture delivery. The concentration (or volume) of the oxidant gas or oxidant vapor in the gas mixture can be substantially stable, for example, if the concentration has a standard deviation of up to 5%, or up to 3%, or up to 1% over an hour.

For example, the oxidant gas or oxidant vapor source 150 in FIG. 1A can be configured to provide a substantially stable (or substantially constant) concentration of hydrogen peroxide vapor in the gas mixture over time (e.g., for about an hour), either through the use of a carrier gas or by using a vacuum to directly draw the hydrogen peroxide vapor from the oxidant gas or oxidant vapor source 150. In some cases, the hydrogen peroxide vapor concentration in the gas mixture is substantially stable over time with a hydrogen peroxide concentration by volume from 500 parts per million by volume (ppmv) to 4000 ppmv, or from 100 ppmv to 100,000 ppmv, or greater than 1000 ppmv, or greater than 0.1% by volume, or greater than 1%, or greater than 2.5%, or greater than 10%, or from 0.1% to 10%, or from 0.1% to 2.5%, or from 1% to 10%, or from 1% to 2.5%, or from 2.5% to 10%, or from 1% to greater than 10%.

The hydrogen peroxide source (e.g., oxidant gas or oxidant vapor source 150 in FIG. 1A) used to deliver hydrogen peroxide vapor to the plasma chamber (or other system component, e.g., a storage vessel) in the systems and methods described herein can utilize a carrier gas to deliver the hydrogen peroxide vapor from the source to the plasma chamber, or can use vacuum to directly draw the hydrogen peroxide vapor from the hydrogen peroxide source. In some examples, the hydrogen peroxide source can include a pre-loaded carrier gas in fluid contact with the vapor phase of a multi-component liquid source (e.g., aqueous hydrogen peroxide), and/or a non-aqueous (or anhydrous) hydrogen peroxide solution having a vapor phase separated from the hydrogen peroxide solution by a membrane.

The hydrogen peroxide sources described herein (e.g., oxidant gas or oxidant vapor source 150 in FIG. 1A) are uniquely capable of providing controlled concentrations of hydrogen peroxide vapor that are substantially stable over time. According to Raoult's Law, when the vapor phase of a liquid solution is continuously swept away by a carrier gas, the more volatile component will evaporate more quickly than the less volatile component, resulting in a dynamic (or changing) concentration of the components in the liquid solution, and likewise, a dynamic (or changing) concentration of the components in a vapor produced from the liquid solution. If evaporation of the more volatile component continues, the solution will become more concentrated for the less volatile component, and in some cases (e.g., aqueous hydrogen peroxide solutions), this may take a stable solution and convert it to a highly concentrated hazardous material. The hydrogen peroxide sources of the systems and methods described herein overcome such limitations and are configured to deliver stable concentrations of a vapor of hydrogen peroxide over time, for example, by using a pre-loaded carrier gas in fluid contact with the vapor phase of a multi-component liquid source, and/or using a non-aqueous (or anhydrous) hydrogen peroxide solution having a vapor phase separated from the hydrogen peroxide solution by a membrane.

In some examples, the hydrogen peroxide source of the systems and methods described herein (e.g., oxidant gas or oxidant vapor source 150 in FIG. 1A) includes one or more components made from the metal alloy (e.g., a zirconium alloy, or Zr 702), and can include: (a) a multi-component liquid source (e.g., containing aqueous hydrogen peroxide, or a solution containing hydrogen peroxide and a solvent) having a vapor phase optionally separated from the liquid source by a membrane; (b) a pre-loaded carrier gas source that is in fluid contact with the vapor phase, wherein the pre-loaded carrier gas comprises a carrier gas and at least one component of the liquid source; and (c) an apparatus for delivering a gas stream comprising at least one component of the liquid source. The membrane can be one that is permeable to hydrogen peroxide, particularly a substantially gas-impermeable membrane, e.g., a perfluorinated ion-exchange membrane, such as a NAFION® membrane. In some examples, the apparatus for delivering a process gas containing the gas stream is an outlet of a head space, which contains the vapor phase, connected directly or indirectly to a chamber, allowing the process gas containing gas stream to flow from the head space to the chamber. Methods for delivering the hydrogen peroxide from such a source can include adjusting the operating conditions, for example, the temperature and pressure of the pre-loaded carrier gas, flow rate of the carrier gas, the concentration of the liquid source, and the temperature and pressure of the liquid source, such that the hydrogen peroxide can be precisely and safely delivered as a process gas.

In some examples, the hydrogen peroxide source of the systems and methods described herein (e.g., oxidant gas or oxidant vapor source 150 in FIG. 1A) includes one or more components made from the metal alloy (e.g., a zirconium alloy, or Zr 702), and can include: (a) an aqueous hydrogen peroxide source and a gas phase provided by the aqueous hydrogen peroxide source, wherein the aqueous hydrogen peroxide source comprises hydrogen peroxide at an initial concentration, and wherein the gas phase comprises hydrogen peroxide and water; (b) a carrier gas in fluid contact with the gas phase, whereby a hydrogen peroxide gas stream is formed, and whereby upon formation of the hydrogen peroxide gas stream the concentration of hydrogen peroxide in the aqueous hydrogen peroxide source increases to a second concentration that is higher than the initial concentration; (c) a fill tube made from the metal alloy (e.g., a zirconium alloy, or Zr 702) that replenishes the aqueous hydrogen peroxide source using an aqueous hydrogen peroxide solution comprising hydrogen peroxide at a third concentration that is lower than the second concentration; and (d) an apparatus that delivers the hydrogen peroxide gas stream to the material that is to be modified, wherein the delivered hydrogen peroxide gas stream comprises hydrogen peroxide at a substantially stable steady-state concentration. For example, maintaining a hydrogen peroxide vapor concentration in the gas mixture with a standard deviation of within 3% or up to 5% of the mean for an hour would be considered substantially stable (or relatively constant).

In some examples, the hydrogen peroxide source of the systems and methods described herein (e.g., oxidant gas or oxidant vapor source 150 in FIG. 1A) includes one or more components made from the metal alloy (e.g., a zirconium alloy, or Zr 702), and can include: (a) a non-aqueous (or anhydrous) hydrogen peroxide solution having a vapor phase separated from the hydrogen peroxide solution by a membrane; (b) a carrier gas or vacuum in fluid contact with the vapor phase; and (c) an apparatus for delivering a gas stream comprising hydrogen peroxide from the source to the plasma chamber (or other system component, e.g., a storage vessel). The membrane can be, for example, a perfluorinated ion-exchange membrane, such as a NAFION® membrane. In some examples, the apparatus for delivering a gas stream comprising hydrogen peroxide is an outlet of a head space, containing the vapor phase, that is connected directly or indirectly to the chamber, allowing the hydrogen peroxide containing gas stream to flow from the head space to the chamber. By adjusting the operating conditions of the systems and devices, for example, the temperature and pressure of the carrier gas or vacuum, the concentration of the hydrogen peroxide solution, and the temperature and pressure of the hydrogen peroxide solution, hydrogen peroxide vapor can be precisely and safely delivered in the gas mixture. In some examples, the amount of hydrogen peroxide in the vapor phase and delivered to the plasma chamber can be controlled by adding energy to the hydrogen peroxide solution, e.g., thermal energy, rotational energy, or ultrasonic energy. In some cases, methods for operating such a hydrogen peroxide source can include: (a) providing a non-aqueous hydrogen peroxide solution having a vapor phase separated from the hydrogen peroxide solution by a membrane; (b) contacting a carrier gas or vacuum with the vapor phase; and (c) delivering a gas stream comprising substantially anhydrous hydrogen peroxide to the plasma chamber.

The multi-component liquid solutions and/or the non-aqueous hydrogen peroxide solutions of the sources described above can be, for example, non-aqueous solutions containing alcohols, polyalcohols, phenols, lactones, amides, esters, polyesters, ethers, carboxylic acids, polycarboxylic acids, sulfonic acids, sulfinic acids, phosphonic acids, phosphinic acids, organic solvents, inorganic solvents, aromatic compounds, polyaromatic compounds, heterocyclic compounds, including polyheterocyclic compounds, fluorinated ethers, fluorinated alcohols, fluorinated sulfonic acids, fluorinated carboxylic acids, polycarboxylic acids, fluorinated phosphonic acids, deep eutectic solvents, such as those disclosed in U.S. Pat. No. 3,557,009 and herein incorporated by reference, and combinations thereof that do not contain substantial amounts of water. Examples of solvents for such multi-component liquid solutions and/or non-aqueous hydrogen peroxide solutions include diethyl phthalate, propylene carbonate, triethylphosphate, polyvinylpyrrolidone, polyvinylalcohol, polyvinylacetate-polyvinylpyrrolidone co-polymer, mellitic acid, benzenehexol, tetrahydrobenzoquinone, 1,8-octanediol, 2,6-dichlorophenol, acridine, 8-hydroxyquinoline, benzylic acid, 1,4-dioxane, amyl acetate, DMF, DMSO, dimethylacetamide, 2-ethyl-1-hexanol, furfuryl alcohol, 2-octanol, 2-methyl-2-heptanol, and combinations thereof.

In some examples, the oxidant gas or oxidant vapor sources of the systems and methods described herein (e.g., oxidant gas or oxidant vapor source 150 in FIG. 1A) can include a storage device for a process solution containing a liquid oxidant (e.g., hydrogen peroxide). The liquid oxidant (e.g., hydrogen peroxide) storage device can include: a housing made from the metal alloy (e.g., a zirconium alloy, or Zr 702) with a wick material disposed therein; a process solution contained within the housing and in fluid contact with the wick material such that the solution is adsorbed onto the wick material, thereby diluting the solution within the wick material; and a head space contained within the housing and separated from the process solution by the wick material. The process solution contains liquid oxidant (e.g., hydrogen peroxide), and optionally one or more other components (e.g., water, solvent, or any of the liquids described herein). In some cases, the process solution contains anhydrous liquid oxidant (e.g., anhydrous hydrogen peroxide). In various examples, the housing is configured to allow a carrier gas to flow through the head space or is configured to allow a vacuum to be drawn through the head space to produce a gas stream comprising a gas phase of the process solution to deliver the gas stream to the plasma chamber (or other system component, e.g., a storage vessel). In some examples, the quantity of the process solution in the device is about 30% to 1900% by weight of the process solution/wick material complex, or is about 30% to 800% by weight of the process solution/wick material complex, or is about 30% to 100% by weight of the process solution/wick material complex, or is greater than 30%, greater than 50%, greater than 70%, greater than 90%, greater than 99%, greater than 100%, greater than 1000%, or greater than 1900% by weight of the process solution/wick material complex.

In some examples, the wick material of the devices described above is a porous structure with a surface area ranging from 100 to 1000 m²/g. In various examples, the wick material is configured to adsorb over 42% by mass (or “w/w”), or to absorb over 50% w/w, or over 100% w/w, or over 200% w/w, or over 800% w/w, or over 1000% w/w, or over 1900% w/w liquid oxidant (e.g., hydrogen peroxide). In some examples, the concentration of the liquid oxidant solution is below 30% w/w. In some examples, the concentration of the liquid oxidant solution is stable over time, such as over a period of time that is no less than approximately 1 hour, or no less than 100 hours. In some examples, the concentration of the oxidant vapor (e.g., hydrogen peroxide vapor) output from the device is stable over time, for example, approximately 1 hour.

In some examples, the wick material is formed as a fabric, a powder, one or more bricks, one or more blocks, one or more beads, one or more particles, one or more extrudates, or one or more pellets. In some examples, the wick material is a non-woven fabric that has been treated with a mechanical finishing process, such as spun bonding, needle bonding, perforation bonding, carding, and any combination thereof. In some examples, the non-woven fabric is a polytetrafluoroethylene (PTFE) fabric. In some examples, the wick material is formed as a mesh. In some examples, the wick material is made of, or includes, the metal alloy (e.g., a zirconium alloy, or Zr 702), or a zirconium oxide material. In some examples, the wick material is formed from a material such as alumina, aluminum oxide, titanium dioxide, silica, silicon dioxide, quartz, activated carbon, carbon molecular sieve, carbon pyrolyzate, polytetrafluoroethylene (PTFE), polyester (PE), polyethylene terephthalate (PET), polyethylene/polyethylene terephthalate co-polymer, polypropylene (PP), rayon, zirconium oxide, zeolite, high silica zeolite, polymethylpentene (PMP), polybutylene terephthalate (PBT), polyethylene/polypropylene co-polymers, Hydrophilic High Density Polyethylene (HDPE), Hydrophobic High Density Polyethylene (HDPE), Hydrophilic UHMW Polyethylene, Hydrophobic UHMW Polyethylene, perfluoroalkoxy alkane (PFA), polyvinylidene fluoride (PVF), silk, tencel, sponge materials, polyethylene glycol (PEG), polyvinyl alcohol (PVA), and/or polyvinylpyrrolidone (PVP), polypyridine, polyacrylates, polyacrylic acid, polyacrylic acid/acrylate co-polymers, polycarbonates, polyacrylamides, polyacrylate/acrylamide co-polymers, cellulosic materials, and any combination thereof. In some examples, the mesh substrate is spiral-wound within the housing.

In some examples, the above liquid oxidant storage device includes a separator disposed adjacent to the mesh, wherein the separator is configured to support and separate layers of the spiral-wound mesh. In some examples, the separator is made of, or includes, the metal alloy (e.g., a zirconium alloy, or Zr 702), or a zirconium oxide material. In certain examples, the separator is formed from PTFE.

In some examples, the wick material is a hydrogel selected from the group consisting of polyethylene glycol (PEG), polyvinyl alcohol (PVA), polyvinylpyrrolidone (PVP), polypyridine, and any combination thereof. In various examples, the hydrogel is a 20% PEG hydrogel or a 40% PEG hydrogel. In some examples, the hydrogel is wrapped in a PTFE mesh and/or may further include a separator disposed adjacent to the mesh.

In some examples, a method for delivering the oxidant gas or oxidant vapor using the oxidant gas or oxidant vapor sources described herein (e.g., oxidant gas or oxidant vapor source 150) includes contacting the process solution containing liquid oxidant (e.g., hydrogen peroxide) with the wick material within the enclosed housing (made from the metal alloy) such that the solution is adsorbed onto the wick material, thereby diluting the process solution within the wick material; exposing the wick material to a carrier gas or a vacuum, thereby forming a gas stream comprising a gas phase of the process solution; and delivering the gas stream to a chamber, or plasma chamber, or other component of the system. The housing may be configured to allow the carrier gas to flow through a head space contained within the housing or is configured to allow vacuum to be drawn through the head space, and the head space may be separated from the process solution by the wick material.

In some examples an oxidant gas or oxidant vapor delivery system includes the liquid oxidant (e.g., hydrogen peroxide) process solution provided within the housing (made from the metal alloy), wherein the process solution is in contact with a wick material disposed within the housing such that the solution is adsorbed onto the wick material, thereby diluting the process solution within the wick material. The chemical delivery system may also include a carrier gas or vacuum in fluid contact with the gas phase in the head space of the process solution, thereby forming a transportable gas stream within the head space. The chemical delivery system may further include an apparatus in fluid communication with the housing and used for delivering the gas stream to a chamber (or other component of the system). In some examples, the housing allows the carrier gas to flow through a head space contained within the housing or allows vacuum to be drawn through the head space.

The oxidant gas or oxidant vapor sources described herein (e.g., oxidant gas or oxidant vapor source 150), including the liquid oxidant (e.g., hydrogen peroxide) process solution and the wick material, can be coupled to gas delivery systems including various components with the metal alloy (e.g., a zirconium alloy, or Zr 702) for containing and controlling the flow of the gases and liquids used therein. For example, the gas delivery systems (e.g., gas delivery system 160) may include one or more mass flow controllers, valves, check valves, filters, pressure gauges, gas sensors, regulators, rotameters, and pumps. The sources and gas delivery systems provided herein may also include various heaters, thermocouples, and temperature controllers to control the temperature of various components of the systems and steps of the methods.

In some examples, the systems and methods described herein include oxidant gas or oxidant vapor sources (such as those described above) configured to provide and maintain a molar ratio of water to hydrogen peroxide that is substantially stable over time (or is maintained at a substantially or relatively constant value over time). The molar ratio of water to hydrogen peroxide that is substantially stable over time in the gas mixture can be substantially stable, for example, if the molar ratio (or the concentration of the hydrogen peroxide and the concentration of the water) is maintained to within 1%, or within 3%, or within 5% of the mean for an hour of gas mixture delivery. The molar ratio of water to hydrogen peroxide that is substantially stable over time in the gas mixture can be substantially stable, for example, if the molar ratio has a standard deviation of 1%, or 3%, or up to 5% over an hour. For example, the hydrogen peroxide source 150 in FIG. 1A can be configured to provide a substantially constant concentration of hydrogen peroxide vapor and water in the gas mixture, either through the use of a carrier gas or by using a vacuum to directly draw the hydrogen peroxide vapor from the hydrogen peroxide source 150. The hydrogen peroxide vapor and water concentrations can be any of those described herein.

The conditions within chamber 110 can include pressures from 1 mTorr to 1000 Torr, from 0.1 Torr to 10 Torr, or about 0.5 Torr, or about 5 Torr. The flow rate of gas into chamber 110, or the flow rate of a carrier gas through oxidant gas or oxidant vapor source 150) can be from 10 sccm to 200 Lpm, or from 10 sccm to 10 Lpm, or from 10 sccm to 1 Lpm, or from 500 sccm to 5000 sccm. The flow rate of oxidant gas or oxidant vapor (e.g., hydrogen peroxide vapor) can be substantially stable over time, and the variability in the flow rate over time can also be small (e.g., with a standard deviation of up to 5%, or up to 3%, or up to 1% over the process time).

FIG. 1B is an example of a conduit that is made from the metal alloy, which is Zr 702 in this case. The short conduit 182a was a control sample that was not exposed to H₂O₂. The short conduit 182a was cleaned and passivated. The longer conduit 182b was cleaned, passivated, and then exposed to H₂O₂ vapor and condensate. The visual appearance of conduit 182a and that of conduit 182b (after exposure to H₂O₂ vapor and condensate) were the same after exposure.

FIGS. 1C-1D show a schematic of an example of a face seal gland that can be made from the metal alloy (e.g., a zirconium alloy, or Zr 702), in accordance with some examples. View 102 shows a cross-section along plane A-A shown in front-side view 106. View 104 is a detailed cross-section of the region B shown in cross-section view 102. View 108 is a right view or an elevation, with respect to front-side view 106. The face seal gland can be used to couple a conduit to another conduit or component, and prevent gas or liquid leakage in the radial direction with respect to the axis 184. This is an example of a component of a gas delivery system where there can be condensation of oxidant gas or oxidant vapor (e.g., hydrogen peroxide) since the pressure could change as the gas passes through the face seal gland component. Not to be limited by theory, dissimilar materials can conduct heat differently, which can cause cold spots and condensation. Additionally, condensation can occur in gas delivery system components where the internal diameter (ID) expands due to the Joule-Thomson effect.

FIGS. 1E-1G show isometric and side-view schematics and an image of an example of a component of an oxidant source, a hydrogen peroxide source in this example, which is a bulkhead fitting between the head space of the hydrogen peroxide source and an outlet of the source, that can be made from the metal alloy (e.g., a zirconium alloy, or Zr 702). This is an example of a component of a hydrogen peroxide source where there can be condensation of hydrogen peroxide since there can be a cold spot caused by the bulkhead fitting and the hardware used to attach the bulkhead fitting. Bulkhead fittings are bolted to a bulkhead and include a structure to support tubing. This structural connection can become a thermal leakage path, which can lead to localized cold spots that cause condensation and corrosion. FIG. 1G shows an example of a 316L stainless steel example bulkhead fitting after use wherein it was exposed to hydrogen peroxide gas, vapor, and/or condensate. Corrosion was observed in the interior of the bulkhead fitting on surfaces that were exposed to the hydrogen peroxide.

FIG. 1H shows a schematic example of an oxidant gas or oxidant vapor source 150, such as a hydrogen peroxide source, in accordance with some examples. The oxidant gas or oxidant vapor source 150 can include a housing 152 made from the metal alloy (e.g., a zirconium alloy, or Zr 702). A solution containing liquid oxidant (e.g., hydrogen peroxide) is in region 154, and a head space 155 contains oxidant gas or oxidant vapor (e.g., hydrogen peroxide vapor). A heater (not shown) can be used to heat the solution in region 154 to form the oxidant gas or oxidant vapor in head space 155. In some cases, region 154 can include a substrate material that absorbs the solution as described above. In some cases, region 154 is separated from head space 155 using a membrane, as described above. Bulkhead fitting 158 is similar to the bulkhead fitting in FIGS. 1E-1G, and can also be made from the metal alloy (e.g., a zirconium alloy, or Zr 702). Optional inlet 157 can be used to flow a carrier gas through head space 155 to transport the oxidant gas or oxidant vapor out of the oxidant gas or oxidant vapor source 150 through the bulkhead fitting 158. In some cases, oxidant gas or oxidant vapor source 150 can include an injector tube (not shown) configured to flow carrier gas across a surface of the membrane or substrate. In some cases, the injector tube can be made from the metal alloy.

In some cases, inlet 157 can be made from the metal alloy (e.g., a zirconium alloy, or Zr 702) to prevent corrosion and particle generation. For example, a cold spot could cause local condensation of hydrogen peroxide vapor from the head space 155 onto the inlet 157 at a local cold spot (e.g., onto the outside diameter of the inlet 157 where the inlet 157 meets the inner wall of the chamber 152). Alternatively, a vacuum can be used to transport the oxidant gas or oxidant vapor out of the oxidant gas or oxidant vapor source 150 through the bulkhead fitting 158 as described herein. Bulkhead fitting 158 can also be coupled to a gas delivery system, as described herein.

For example, the oxidant gas or oxidant vapor source 150 can contain a concentrated liquid H₂O₂ solution in region 154, a concentrated H₂O₂ vapor in head space 155, a perfluorinated ion-exchange membrane, such as a NAFION® membrane (e.g., between the head space 155 and region 154, or in the solution such that the gas can enter the membrane), and a housing 152 and bulkhead fitting 158 made from a zirconium alloy (e.g., Zr 702). The liquid H₂O₂ can have limited decomposition when heated, for example due to the components of the hydrogen peroxide source 150 that contact the hydrogen peroxide being made from metal alloy (e.g., a zirconium alloy, or Zr 702). The oxidant gas or oxidant vapor source 150 can then be used to deliver concentrated H₂O₂ vapor to a chamber or process equipment using a gas delivery system. In some cases, the membrane or substrate is made from a material (e.g., NAFION®) that is compatible with the metal alloy and the hydrogen peroxide. For example, the membrane or substrate does not significantly corrode or become brittle when exposed to the oxidant in the presence of the metal alloy.

In some cases, the concentration of the oxidant gas or oxidant vapor (e.g., H₂O₂ vapor) in the gas delivered to the gas delivery system and/or to a downstream chamber or process tool is substantially the same as the concentration of oxidant gas or oxidant vapor in the head space 155. In some cases, the pressure of the gas can change in the gas delivery system; however, the ratio of oxidant gas or oxidant vapor to other components in the gas (e.g., water vapor) is substantially the same in the gas delivery system and the head space 155 because the oxidant gas or oxidant vapor does not substantially decompose in the head space or the gas delivery system.

In some cases, the oxidant gas or oxidant vapor source 150 contains a solution of hydrogen peroxide and water in region 154, and outputs a gas including hydrogen peroxide vapor and water vapor. For example, when a carrier gas is used to transport the hydrogen peroxide vapor, the solution in region 154 can have a hydrogen peroxide concentration greater than about 30%, or greater than about 60%, and the hydrogen peroxide vapor in head space 155 can have an H₂O₂: water ratio of about 1:2, or about 1:4, or about 1:10. In another example, when a vacuum is used to transport the hydrogen peroxide vapor, the solution in region 154 can have a hydrogen peroxide concentration greater than about 10%, or greater than about 50%, or greater than about 98%, and the hydrogen peroxide vapor in head space 155 can have an H₂O₂: water ratio of about 1:10, or about 1:1, or about 10:1.

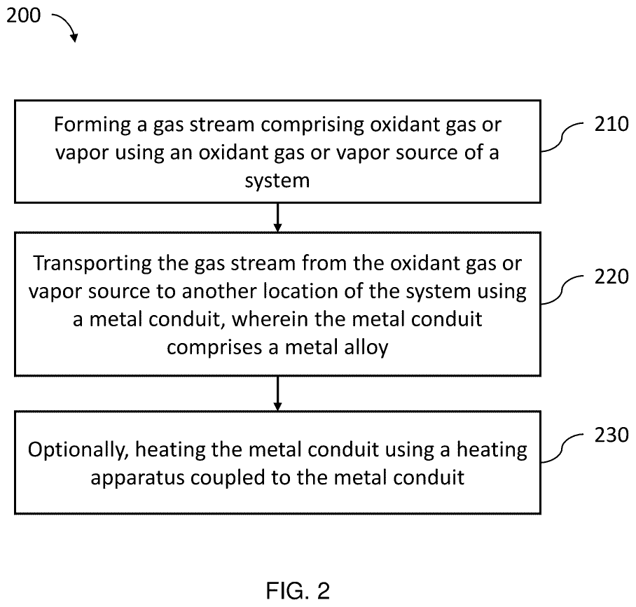

FIG. 2 is a flowchart of an example method 200 for oxidant gas or oxidant vapor generation and delivery, in accordance with some examples. For example, the oxidant gas or oxidant vapor can include one or more of hydrogen peroxide (H₂O₂), ozone (O₃), oxygen (O₂), hypochlorous acid (HOCl), nitric acid (HNO₃), nitrous oxide (N₂O), and nitrogen dioxide/dinitrogen tetroxide (NO₂/N₂O₄). At block 210, a gas stream is formed or generated comprising oxidant gas or oxidant vapor using an oxidant gas or oxidant vapor source of a system. The oxidant gas or oxidant vapor source can include the metal alloy (e.g., a zirconium alloy, or Zr 702), in some cases. At block 220, the gas stream is transported from the oxidant gas or oxidant vapor source to another location of the system using a metal conduit, wherein the metal conduit comprises the metal alloy (e.g., a zirconium alloy, or Zr 702). At optional block 230, the metal conduit is heated using a heating apparatus coupled to the metal conduit.

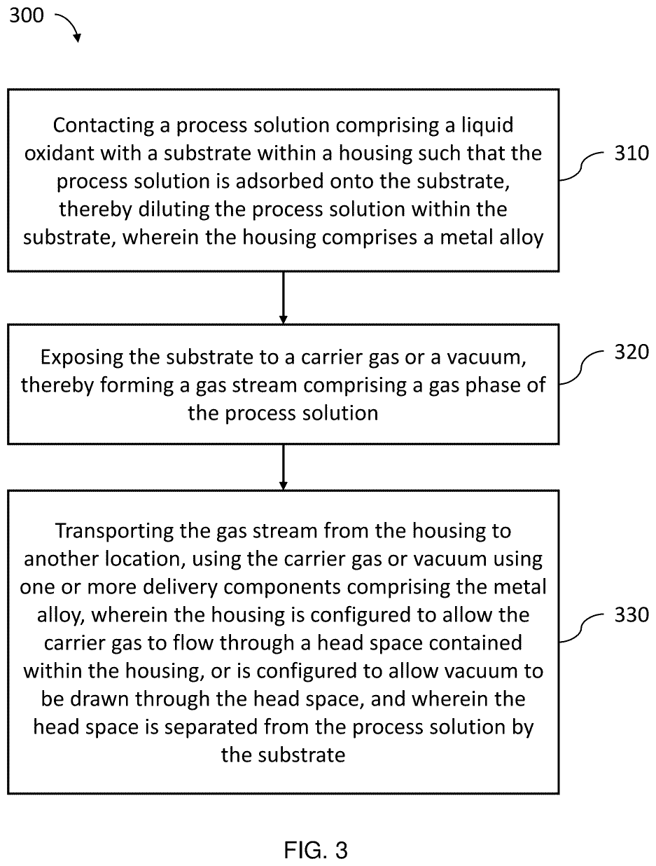

FIG. 3 is a flowchart of an example method 300 for oxidant gas or oxidant vapor generation and delivery, in accordance with some examples. At block 310, a process solution comprising a liquid oxidant (e.g., hydrogen peroxide, hypochlorous acid, and/or nitric acid) contacts a substrate within a housing such that the process solution is adsorbed onto the substrate. The process solution is thereby diluted within the substrate. The housing comprises the metal alloy (e.g., a zirconium alloy, or Zr 702). At block 320, the substrate is exposed to a carrier gas or a vacuum, thereby forming a gas stream including a gas phase of the process solution. At block 330, the gas stream is transported from the housing to another location, using the carrier gas or vacuum using one or more delivery components including the metal alloy. The housing can be configured to allow the carrier gas to flow through a head space contained within the housing, or can be configured to allow vacuum to be drawn through the head space, where the head space is separated from the process solution by the substrate.

In some cases, the systems and methods described herein can be used to generate and deliver combinations of oxidant gases or oxidant vapors. For example two or more of hydrogen peroxide (H₂O₂), ozone (O₃), oxygen (O₂), hypochlorous acid (HOCl), nitric acid (HNO₃), nitrous oxide (N₂O), and nitrogen dioxide/dinitrogen tetroxide (NO₂/N₂O₄) can be mixed in a gas stream and delivered to a chamber (e.g., chamber 110) using a gas deliver system (e.g., gas delivery system 160). For example, ozone or hydrogen peroxide gas or vapor can be mixed with oxygen in a gas stream. In another example, nitric acid and nitrous oxide can be mixed in a gas stream. In some cases, a single oxidant gas or oxidant vapor source (e.g., oxidant gas or oxidant vapor source 150) can be used to generate more than one oxidant gas or oxidant vapor. For example, ozone generators typically produce a mixture of ozone and oxygen. In another example, two or more oxidant gas or oxidant vapor sources, each producing a different oxidant gas or oxidant vapor, can be coupled to one gas delivery system to deliver a mixture of the oxidant gas or oxidant vapor species. The metal alloys (e.g., Zr, Zr alloys with a high Zr content (e.g., Zr 702), Hf, Hf alloys with a high Hf content, Ta, and Ta alloys with a high Ta content) of the systems and methods described herein can be used in these systems, and can be beneficial to limit an amount of decomposition of the oxidant gas or oxidant vapor mixture, and/or limit the generation of particles formed from the metal alloy when exposed to the oxidant gas or oxidant vapor mixture. In some cases, a surface of the metal alloy in the systems and methods described herein is passivated.

In some cases, the components of the oxidant gas or oxidant vapor source 150 and the gas delivery system 160 of system 100 in FIG. 1A that come into contact with the oxidant gas or oxidant vapor can be made from the metal alloy (e.g., a zirconium alloy, or Zr 702). Conduits 180a and 180b can also be made from the metal alloy (e.g., a zirconium alloy, or Zr 702). For example, the face seal gland shown in FIGS. 1C-1D and/or the bulkhead fitting shown in FIGS. 1E-1G can be made from the metal alloy, and can be parts of the oxidant gas or oxidant vapor source 150 and the gas delivery system 160. The metal alloy in these systems can enable a gas stream containing the oxidant gas or oxidant vapor entering chamber 110 to be substantially free of particles.

In some cases, the gas stream delivered to the process chamber (e.g., chamber 110 in FIG. 1A) can be comprised of one or more oxidant gases or vapors in combination with water. When an oxidant gas or oxidant vapor is used in combination with water, there is a possibility of condensation of one or more species in the gas stream, which can cause accelerated corrosion. For example, a gas stream described herein can include water and an oxidant gas or oxidant vapor including one or more of hydrogen peroxide (H₂O₂), ozone (O₃), oxygen (O₂), hypochlorous acid (HOCl), nitric acid (HNO₃), nitrous oxide (N₂O), and nitrogen dioxide/dinitrogen tetroxide (NO₂/N₂O₄). Water vapor can either be mixed with the oxidant gas or oxidant vapor, or water can be generated using the oxidant gas or oxidant vapor. For example, several of the oxidants listed above contain the atoms necessary to form water, hydrogen and oxygen, and can produce water when exposed to a plasma. Additionally, oxidants containing oxygen but not hydrogen can also produce water molecules in a plasma, since hydrogen is likely to be present in the delivery systems and can react with excited oxygen species to form water. The metal alloys (e.g., Zr 702) of the systems and methods described herein can also be beneficial to limit an amount of corrosion of system components, and limit the generation of particles formed from the metal alloy when exposed to the oxidant gas or oxidant vapor in combination with water.

In some examples, a method for delivering a gas can include: forming a gas stream including an oxidant gas or oxidant vapor using an oxidant gas or oxidant vapor source of a system; transporting the gas stream from the oxidant gas or oxidant vapor source to another location of the system using a metal conduit, wherein the metal conduit includes a metal alloy; and optionally, heating the metal conduit using a heating apparatus coupled to the metal conduit. In some examples, the metal alloy limits generation of particles formed from the metal alloy when exposed to the oxidant gas or oxidant vapor. In some examples, the metal alloy limits an amount of decomposition of the oxidant gas or oxidant vapor. In some examples, the metal alloy generates fewer particles than stainless steel, aluminum, ferrous steel, or titanium when exposed to condensed and evaporated oxidant gas or oxidant vapor. In some examples, the metal alloy decomposes the oxidant gas or oxidant vapor less than stainless steel, aluminum, ferrous steel, or titanium does. In some examples, the metal alloy corrodes less than stainless steel, aluminum, ferrous steel, or titanium does when exposed to condensed and evaporated oxidant gas or oxidant vapor. In some examples, the metal alloy includes more than 90% zirconium, hafnium, and/or tantalum. In some examples, the metal alloy includes more than 99% Zr and Hf combined, and less than 5% Hf. In some examples, the metal alloy includes an unpassivated surface. In some examples, the metal alloy includes a passivated surface. In some examples, the metal alloy includes a cleaned and passivated surface. In some examples, the metal alloy includes an oxidized coating.

In some examples, the method above further includes transporting the gas stream from the oxidant gas or oxidant vapor source to another location of the system using the metal conduit and one or more delivery components including the metal alloy, wherein the delivery components can include, but are not limited to, one or more of fittings, valves, flowmeters, filters, pressure controllers, regulators, and fluid sensors, wherein the one or more of fittings, valves, flowmeters, filters, pressure controllers, regulators, and fluid sensors.

In some examples, the gas stream further includes a carrier gas, or the gas stream is transported from the oxidant gas or oxidant vapor source to another location of the system using a vacuum.

In some examples, the systems and methods described herein further include delivering the gas stream to a semiconductor process, wherein the gas stream is substantially free of particles.

In some examples, a gas or vapor delivery system can include: an oxidant gas or oxidant vapor source including an outlet configured to output a gas stream including an oxidant gas or oxidant vapor; a metal conduit including a metal alloy; and optionally, a heating apparatus coupled to the metal conduit configured to heat the metal conduit.

### EXAMPLES

### Example 1: Liquid H₂O₂ Corrosion and H₂O₂ Decomposition Studies (316L Steel Vs. Zr 702)

In this Example, the reactivity of different metal alloys, including 316L steel and a zirconium alloy (Zr 702), at elevated temperature with concentrated liquid hydrogen peroxide (H₂O₂) was quantified.

In initial testing, 316L stainless steel (316L) conduits were used in gas delivery systems for high concentrations of H₂O₂ vapor at elevated temperatures. Under these conditions, some of the 316L conduits developed noticeable changes, indicating chemical reactions were occurring. Specifically, 316L conduits were observed to exhibit rouging, such as a purple, red, orange, or yellow coloring, caused by oxidation of the free iron in the exposed surface. This discoloration is undesirable because it correlated with increased reactivity and solid metal particle generation.

In this Example, perfluoroalkoxy alkane (PFA) containers were filled with 70 wt % liquid H₂O₂, metal samples were submerged in the H₂O₂, and the containers were sealed with vented closures. The containers were loaded into a temperature-controlled water bath, and soaked for approximately 6 hours. After the metal samples cooled down, they were opened and visually inspected. After heating, the liquid density of the H₂O₂ was measured, and the concentration of H₂O₂ was estimated using liquid density (compared to a blank H₂O₂ sample that was also heated but did not include any metal samples). The remaining H₂O₂ was then tested for trace metals using inductively coupled plasma mass spectrometry (ICP-MS). The metal samples were also washed with DI water and inspected for any other visible signs of change.

In some cases, the metal samples were cleaned and passivated before testing. The cleaning included washing in cleanroom grade IPA, rinsing with DI water, followed by ultrasonic cleaning in a CITRAJET™ cleaning solution at elevated temperature. The Zr 702 zirconium alloy was passivated using sulfuric acid (H₂SO₄) after cleaning. The 316L steel samples were passivated using CITRAJET™ after cleaning. Experiments showed that the cleaned and passivated Zr 702 was visually unaffected by exposure to 76 wt % H₂O₂ for 6 hours at 80° C. In other cases, alternative passivation procedures using combinations of HNO₃, HF, H₂SO₄, and H₂O₂ can be used to generate passive layers on zirconium alloys.

The Zr 702 samples did not change color when exposed to liquid H₂O₂. Zr 702 samples were cleaned and passivated, and exposed to 70 wt % liquid H₂O₂ for 10 days. The samples were not visibly affected, did not change color, did not transfer color to cleanroom wipes or cotton swabs, and the H₂O₂ solution also did not become colored.

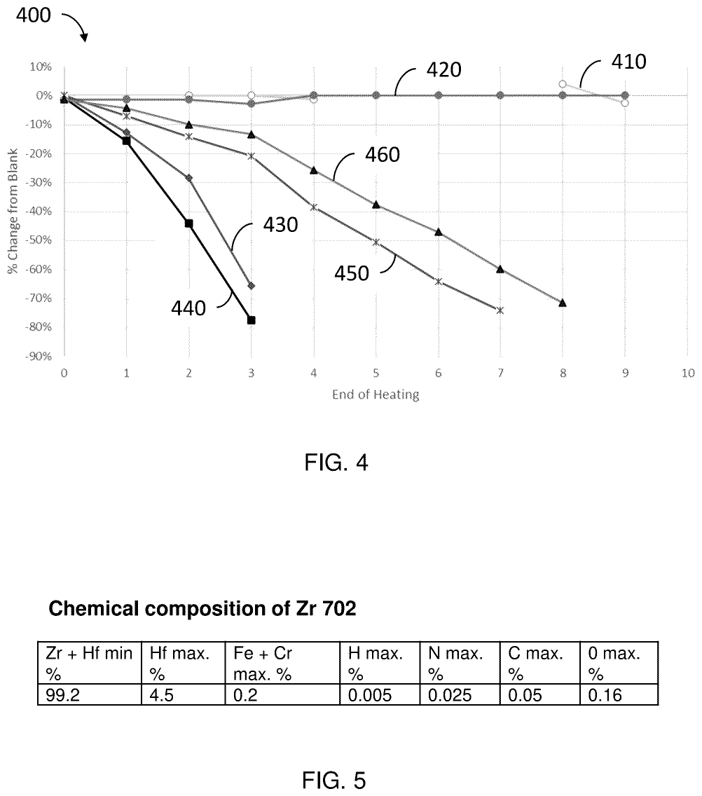

FIG. 4 shows density changes in H₂O₂ solutions that contained the passivated 316L steel and Zr 702 zirconium alloy samples. Two Zr 702 samples and three 316L samples were passivated with CITRAJET™ and covered with 100 mL of 70 wt % H₂O₂. The samples were left in an 80° C. water bath for 6 hours a day along with blank samples with no metals. Samples were left at ambient temperature during weekends and between heating cycles. The density of the solution was taken periodically to estimate H₂O₂ concentration. The 316L passivated steel sample was exposed for a second and third run once the concentration of H₂O₂ was deemed sufficiently low. H₂O₂ solutions were retained after each step for trace metals analysis. The y-axis is the percentage change from the blank, and the x-axis is the number of 6 hour exposures. The trends are shown in FIG. 4, where the data has been normalized to the appropriate sample blanks.

FIG. 4 shows the percent change in density of H₂O₂ liquid normalized to the sample blanks. FIG. 4 shows that the Zr 702 passivated samples 410 and 420 performed the best compared to the 316L steel samples 430 and 440 in reference to hydrogen peroxide decomposition. The blank solution dropped 2 wt % H₂O₂, from 79% to 77%. The Zr 702 sample solutions 410 and 420 dropped about 5% over 9 exposure periods. The 316L sample solutions 430, 440, 450, and 460 on the other hand, dropped more than 60% over 3 to 8 exposure periods.

Hydrogen peroxide solution samples were analyzed for trace metals using ICP-MS. The samples tested included two “blank” samples consisting of diluted H₂O₂ as controls.

FIG. 5 shows an example composition of a zirconium alloy (Zr 702), used in this Example. The sample had 99.2% Zr and Hf combined, and a maximum of 4.5% Hf. Fe and Cr had a maximum concentration of 0.2% combined.

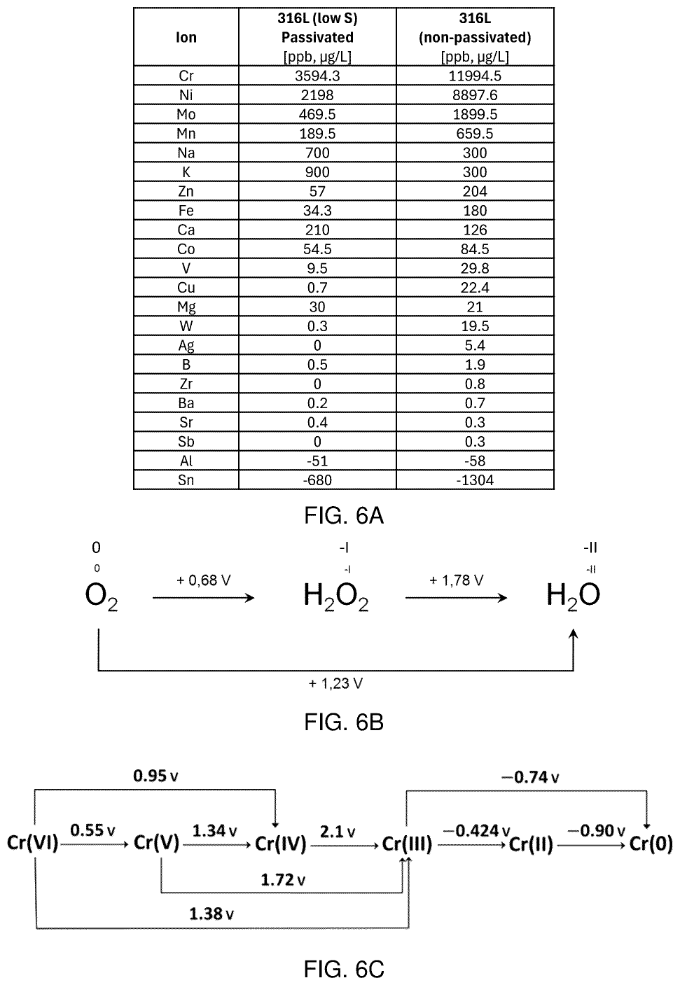

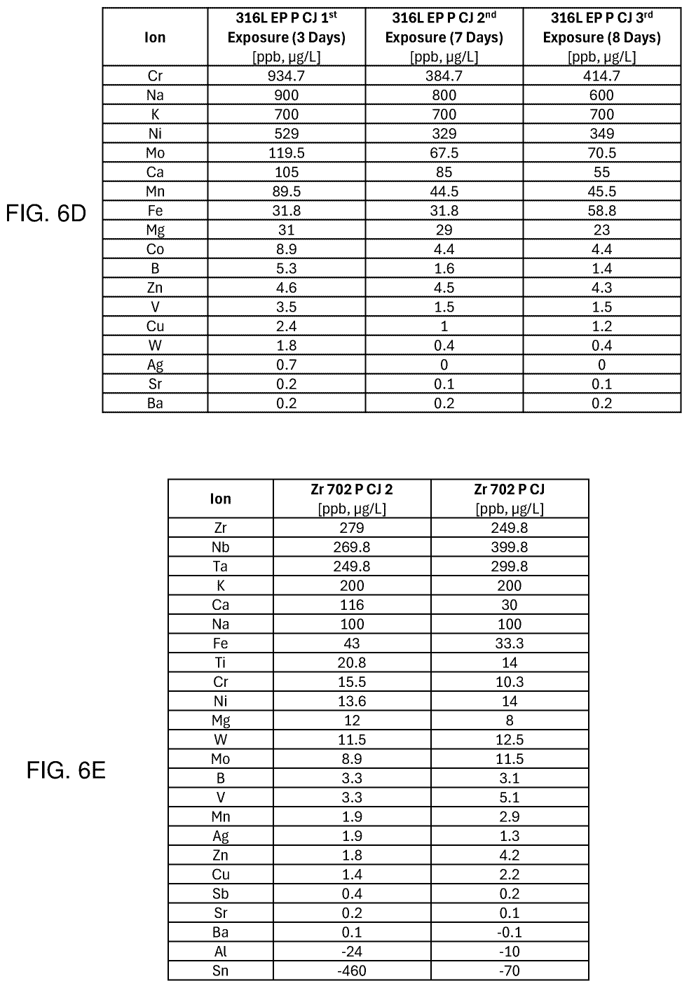

FIG. 6A shows the trace metals results from samples of the H₂O₂ solution exposed to each of the 316L materials. The table in FIG. 6A contains the metal concentration in each sample after subtraction of the relevant H₂O₂ blank. Ions that were below the detection limit in either sample were omitted.

The table in FIG. 6A is sorted from decreasing concentration of ions with respect to the non-passivated sample. The non-passivated sample shows higher levels of almost all ions. Exceptions include sodium, potassium, and calcium, which could be due to environmental and handling contamination. Aluminum and tin have negative values for both samples because the source peroxide contained more than the exposed sample. This indicates that those metals may have either precipitated out of solution, or became incorporated into the metal samples. Additionally, note that the metal samples were removed from the low sulfur sample after only 4 days as opposed to 10 days due to the loss of the H₂O₂ concentration, and the non-passivated sample was only exposed to ambient temperatures.

Chromium, nickel, molybdenum, and manganese are likely present in higher concentration in the data in FIG. 6A due to dissolution of the passive layer. During passivation of steel, iron is dissolved by the acidic solution at a faster rate than chromium, leading to a layer rich in chromium and depleted in iron. This layer is oxidized resulting in chromium (III) oxide (Cr₂O₃) which is insoluble in water, and resistant to further oxidation. Under specific conditions, Cr₂O₃ can be oxidized to chromium (IV) oxide (CrO₃), which is highly soluble in water. The conditions under which this occurs are called the transpassive regions, in which the electrochemical potential between the solution and the passive layer favor dissolution of the passive layer rather than growth. The ion concentrations indicate that both 316L samples entered the transpassive region, and the passive layer was corroded by the H₂O₂.

FIGS. 6B and 6C show Latimer diagrams for chromium and oxygen at pH 0, in which it can be seen that the potential is 1.38V to oxidize Cr (III) to Cr (IV), and the reduction potential of H₂O₂ to H₂O is 1.78V. As H₂O₂ reacts there is sufficient electrochemical potential available in solution to oxidize Cr₂O₃ to CrO₃. Since there are numerous other electrochemical redox reactions happening simultaneously in solution, only some of the energy would be directed towards this particular reaction.

The elevated levels of zirconium, niobium, tantalum, and titanium in the data in FIG. 6A may be due to cross contamination from the cutting wheel used to cut all the tubing samples. Potassium, sodium, and calcium are common environmental contaminants.

FIG. 6D shows data from ICP-MS trace metals analysis of solutions that were used to test a batch of 316L stainless steel pieces. The pieces were electropolished and passivated with CITRAJET™. The pieces were exposed to 70 wt % H₂O₂ in the same manner as the other metal samples. After 3 cycles of 80° C. exposure, the H₂O₂ solution was collected. The pieces were rinsed and exposed to a fresh solution of 70 wt % H₂O₂. After 7 cycles the solution was collected, and the pieces were rinsed and exposed for a third time to 70 wt % H₂O₂. After 8 cycles, the solution was collected, and all the samples were sent for ICP-MS trace metals analysis. The table in FIG. 6D contains the data from the analysis. Values that were unchanged or below baseline were omitted.

The data in FIG. 6D shows that the initial exposure resulted in more chromium, nickel, molybdenum, and manganese ions in solution compared to the 2nd and 3rd exposures. Iron was consistent for the 1st and 2nd exposures. Iron increased for the 3rd exposure which correlates with the appearance of a pale yellow hue of the metal sample. Variation in sodium, potassium, and calcium are like due to minor differences in sample handling.

Returning to FIG. 4, the decomposition of hydrogen peroxide of the steel sample after the first exposure is shown in curve 440, the decomposition of hydrogen peroxide of the steel sample after the second exposure is shown in curve 450, and the decomposition of hydrogen peroxide of the steel sample after the third exposure is shown in curve 460. This data shows that the decomposition rate slowed, but was still much higher than that of the Zr samples in curves 410, 420.

FIG. 6E shows trace metals data from two H₂O₂ samples that were exposed to zirconium alloys (Zr 702). The table in FIG. 6E contains the metal concentration in each sample after subtraction of the relevant H₂O₂ blank. Ions that were below the detection limit in either sample were omitted. The results from the Zr metals analysis are comparable to each other. The dominant ions present in the solution are zirconium, niobium, and tantalum. Potassium and calcium are generally contaminants from the environment or handling. Iron, titanium, chromium, and nickel are likely present due to contamination during the cutting process. The cutting wheel is made from carbon steel and can embed metal particles into the tubing while cutting. Overall, there were less dissolved metals in the H₂O₂ solutions used to soak the zirconium alloy samples compared to those used to soak the 316L steel samples.

The experiments in this Example showed that a zirconium alloy (Zr 702) caused less H₂O₂ decomposition, and corroded less, than a stainless steel (316L). The passive layer of the Zr 702 alloy does not appear to be substantially dissolved by concentrated liquid H₂O₂ under elevated temperature over time. Additionally, the Zr 702 alloy does not substantially decompose concentrated liquid H₂O₂ under elevated temperatures. In contrast, the passive layer of electropolished 316L stainless steel can be dissolved in concentrated H₂O₂ under elevated temperatures over time. Cleaning, passivation, and preexposure can diminish but not halt the rate at which these phenomena occur. Additionally, electropolished 316L stainless steel was also found to decompose concentrated H₂O₂ under elevated temperatures.

### Example 2: Condensing Vapor H₂O₂ Particle Studies (316L Vs. Zr 702)

In this Example, vapor H₂O₂ was condensed on different metal components, and the number of particles generated was measured.

In initial experiments, some corrosion of fittings made from stainless steel was observed and correlated with increased particles in downstream processes. For example, the first metal part on the process line exposed to H₂O₂ vapor is the hydrogen peroxide source bulkhead fitting (e.g., shown in FIGS. 1E-1G), and some visual corrosion was observed. Due to temperature changes, there can be H₂O₂ condensation in the bulkhead fitting. For example, the bulkhead fitting on the right-hand side of FIG. 1G (cut in cross-section) is made from 316L stainless steel and shows some visible signs of corrosion after use.

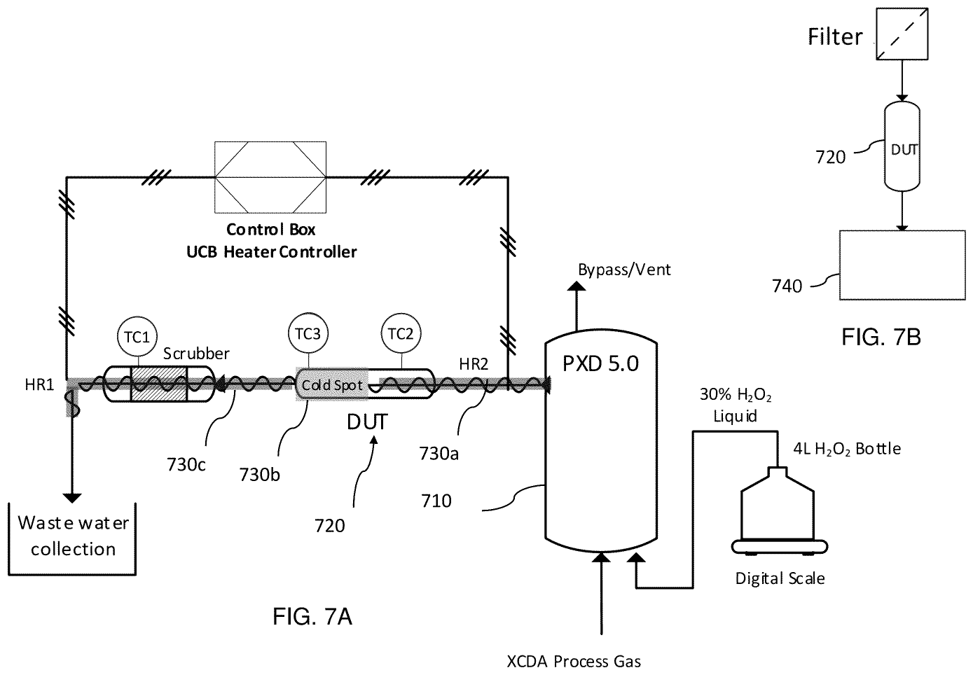

FIGS. 7A and 7B show schematics of the experimental setups used to evaluate the 316L steel and the Zr 702 zirconium alloy in this Example. A hydrogen peroxide source 710 was used to generate a gas stream containing vapor hydrogen peroxide. The vapor hydrogen peroxide was delivered to the sample 720 (device under test, “DUT”) using a heated conduit 730a. A cold spot 730b was formed at the sample 720, and then a second heated conduit 730c was used to transport the hydrogen peroxide to a waste water collection tank. FIG. 7B shows the sample 720 and a particle counter 740. The heated conduits 730a and 730c were heated to a temperature of about 115° C.-125° C., and the cold spot 730b was about 5° C.-10° C. colder. The presence of the cold spot 730b caused hydrogen peroxide vapor to condense in the sample and then evaporate. A dry gas (at 28.3 L/min) was sent through the sample 720 directly after H₂O₂ condensate exposure testing, and the particle counter 740 was used to measure particles with different sizes ranging from about 0.1 microns to 5 microns in size.

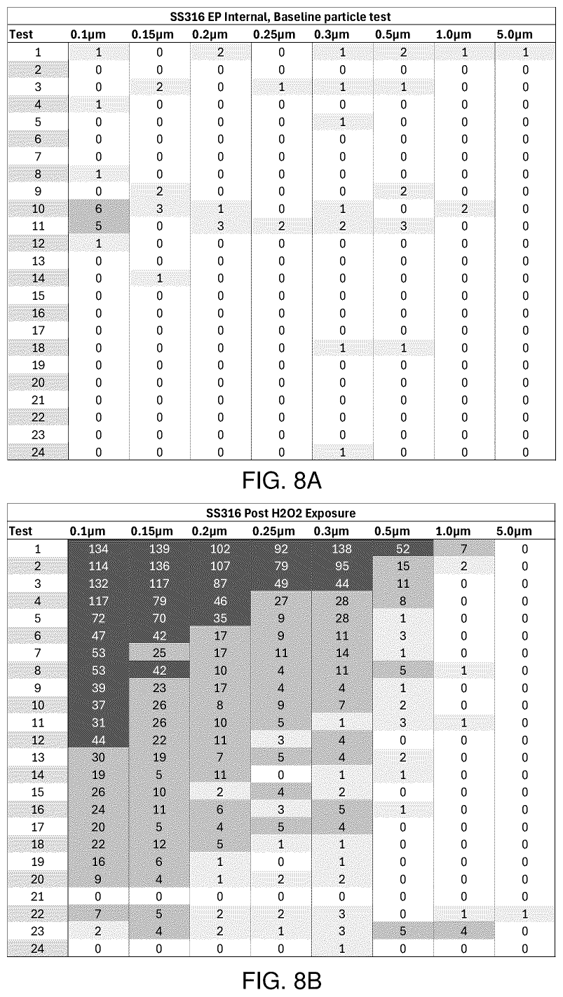

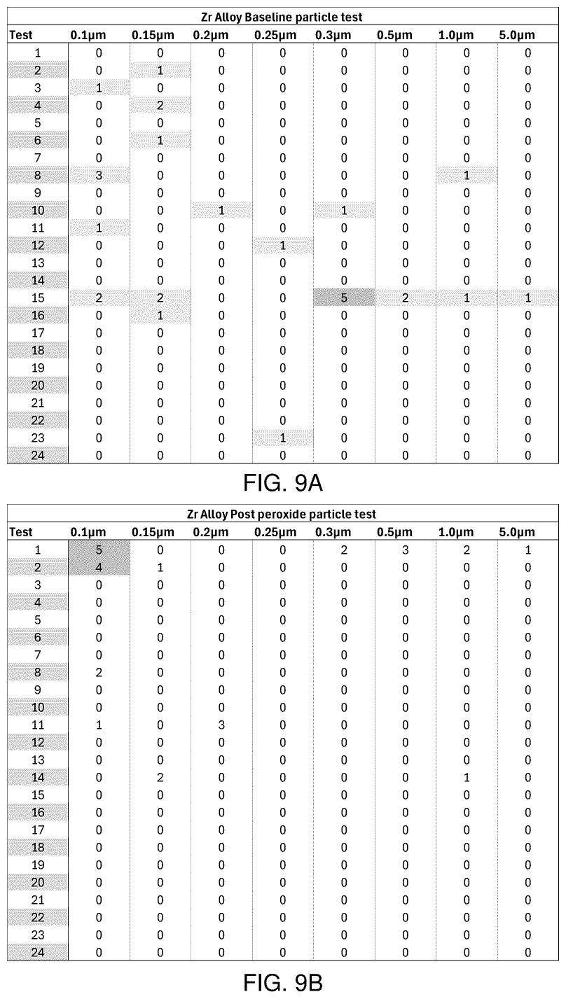

FIGS. 8A-8B show results from 316L stainless steel before and after exposure to H₂O₂ condensate for about 40 hours, respectively. FIGS. 9A-9B show the results from the Zr 702 alloy before and after exposure to H₂O₂ condensate for about 40 hours, respectively. To count the particles, dry gas was sent through the sample for 5 min and the cumulative number of particles counted over the 5 min time period was recorded. These 5 min cumulative particle counts were then performed 24 times in a row. The cells of the tables are shaded reflective of the number of particles.

The table in FIG. 8B show the results of all 24 tests in different particle size ranges, for the 316L stainless steel sample after exposure. These results show, that for small particles (with sizes under about 0.5 microns), the 316L samples produced significantly more particles than the Zr 702 samples after exposure, shown in FIG. 9B. The smallest particles, with sizes about 0.1 microns, were detected at rates of about 100 per minute directly after exposure, and more than 10 per minute were still being detected after 90 min of dry gas was sent through the sample.

The tables in FIGS. 9A-9B show the results of all 24 tests in different particle size ranges, for the Zr 702 zirconium alloy sample. These results show that almost no particles were generated from exposure to the H₂O₂ condensate.

The results of these experiments are striking, and show that metal alloys described herein such as Zr 702 can greatly reduce the amount of particles generated upon exposure to hydrogen peroxide vapor or condensate. The metal alloys like Zr 702 limit the amount of corrosion of the components, and limit the amount of decomposition of H₂O₂ as well, compared to a metal that is more reactive with H₂O₂ such as 316L stainless steel. These results and the results of the previous Example showed that the Zr 702 metal alloy would be suitable for components used to generate and deliver hydrogen peroxide vapor for high purity and low particle applications, such as semiconductor manufacturing, while the 316L stainless steel would not.

### Example 3: Humidified Ozone (O₃) Corrosion Studies (316L Steel Vs. Zr 702)

In this example, corrosion resistance of different types of process tubing was evaluated. 316L steel and Zr 702 tubing were exposed to ozone gas and evaluated for corrosion. Ozone was generated using a semiconductor grade ozone generator that generated high-purity ozone from oxygen via electrical discharge. Moisture (water vapor) was added to the ozone to form a mixture including water vapor, ozone, and optionally other gases (e.g., oxygen and/or nitrogen), which is referred to herein as “humidified ozone.” The corrosion was evaluated using visual inspection and a particle counter.

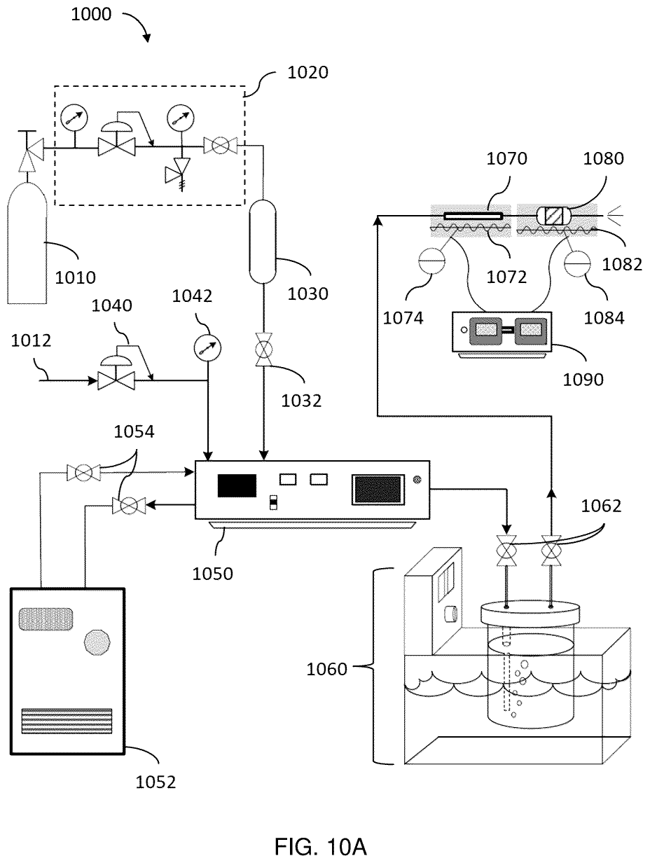

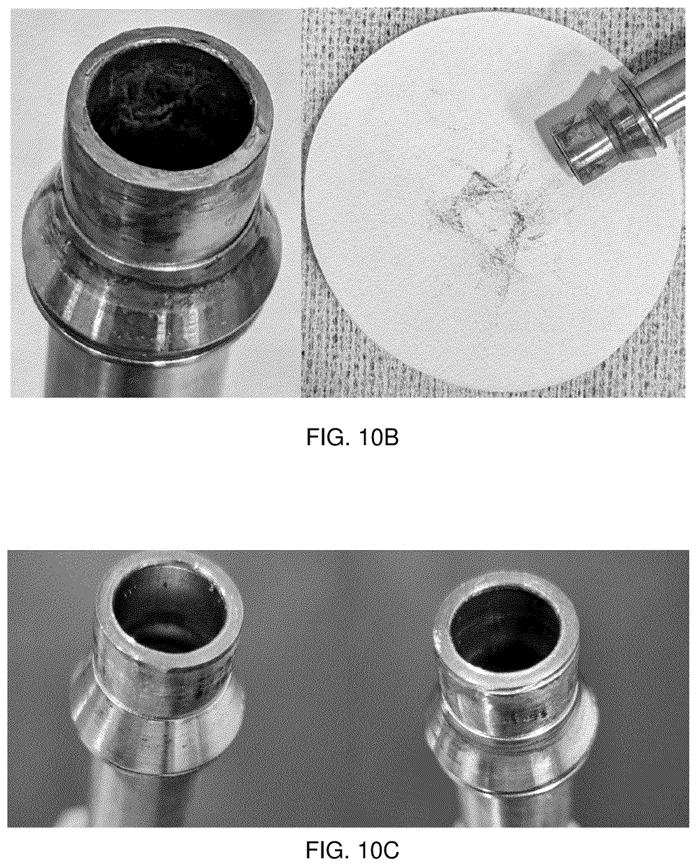

FIGS. 10A and 7B show schematics of the experimental setups used to evaluate the 316L stainless steel and the Zr 702 zirconium alloy in this Example.

FIG. 10A shows a schematic of the experimental setup 1000 used to expose the 316L stainless steel and the Zr 702 samples to the humidified ozone. The experimental setup 1000 included a source of oxygen 1010, which was a research grade oxygen cylinder, coupled to pressure control system 1020, which included a pressure regulator, pressure sensors, an isolation valve, an oxygen purifier 1030, and an oxygen isolation valve 1032. The oxygen was provided to the ozone generator 1050, which was coupled to chiller 1052 via lines with valves 1054. Purified nitrogen gas 1012 was also provided to the ozone generator 1050 using pressure regulator 1040 and pressure sensor 1042. The nitrogen was added in small amounts (e.g., 100 ppmv), which can be beneficial to passivate gas path anomalies capable of destroying the generated ozone. The mixture of ozone, oxygen, and nitrogen with up to 20 wt. % ozone that was output from the ozone generator 1050 was provided to a water bubbler 1060, which was in a temperature-controlled water bath in order to add water vapor to the mixture of ozone and oxygen. The humidified ozone was provided to the device under test (DUT) 1070 using valves 1062. The DUT was heated using a heater 1072 controlled using a thermocouple 1074 positioned to measure the temperature proximal to the DUT. The humidified ozone was provided to a scrubber 1080, which was heated using a heater 1082 controlled using a thermocouple 1084 positioned to measure the temperature proximal to the scrubber.

During the testing, metal tubes made from 316L stainless steel and Zr 702 zirconium alloy were exposed to ozone concentrations between about 125,000 ppmv (i.e., about 18 wt. %). The ozone was mixed with oxygen and a small amount of nitrogen (e.g., 100 ppmv) and had moisture concentrations from about 2 ppmv to about 250,000 ppmv. The oxygen provided into the ozone generator had a purity of about 99.999% and had flow rates from about 5 standard liters per minute (SLM) to about 20 SLM. The metal tubes were about 6″ long with outer diameter (OD) of about ⅜″.

In a first test, a 316L stainless-steel (SS) sample of tube was exposed to humidified ozone to corrode the wetted path. A 5 SLM oxygen input gas stream was used, with the bubbler heater set to 50° C., which resulted in a gas stream of humidified ozone containing about 78 vol. % oxygen, about 11 vol. % ozone, and about 11 vol. % water vapor, with a small amount of nitrogen delivered to the sample. Heat tape was used to heat the SS sample and the scrubber to 100° C. to prevent condensation.

In the first test, the SS sample was inspected after 49 hours of exposure. The outlet of the tube showed signs of corrosion and yellow discoloration consistent with oxidation at elevated temperatures. The interior of the tube showed signs of possible debris on an otherwise smooth reflective surface. The inlet of the sample had similar discoloration but to a lesser degree. The exterior of the sample inlet did not show any signs of corrosion or discoloration. The sample was exposed for a total of 75 hours, after which a PFA tube was used to scrape debris off the interior walls. The PFA tube was rubbed with filter paper to get a visual indication of the scraped material. FIG. 10B shows photographs of the SS sample after the 75 hours of exposure, and the filter paper which shows a fine, dark grey powder. Elemental analysis was performed on the tube used to scrape the material, which showed recovered metals at masses of: Fe=17 μg; Cr=2.5 μg. Due to the large amount of corrosion and debris production that was clearly visible, the sample was not particle tested.

In a second test, a 6″ long sample tube of Zr 702 was exposed to the same corrosive conditions for the same duration, 75 hours total. Stainless steel ferrules were swaged onto the Zr sample tube for connection to the ozone generator outlet and scrubber. After exposure, the inner surfaces of the zirconium tube appeared to be unaffected by the humidified ozone. The stainless steel ferrule at the tubing outlet, however, showed slight signs of corrosion and/or discoloration from exposure. FIG. 10C shows photographs of the inlet (left) and outlet (right) sides of the Zr sample tubing after exposure. The photographs in FIG. 10C show some discoloration on the tube exterior at the outlet near where the tube was swaged onto the stainless fitting (on the scrubber inlet), which could be a source of particles.

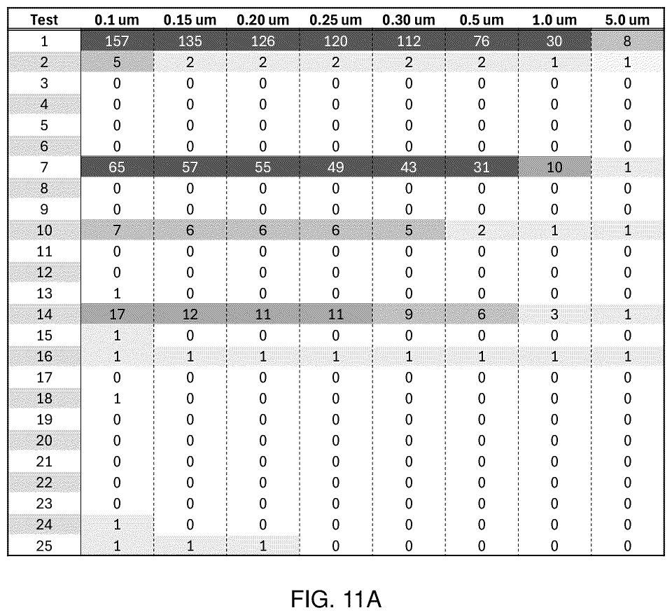

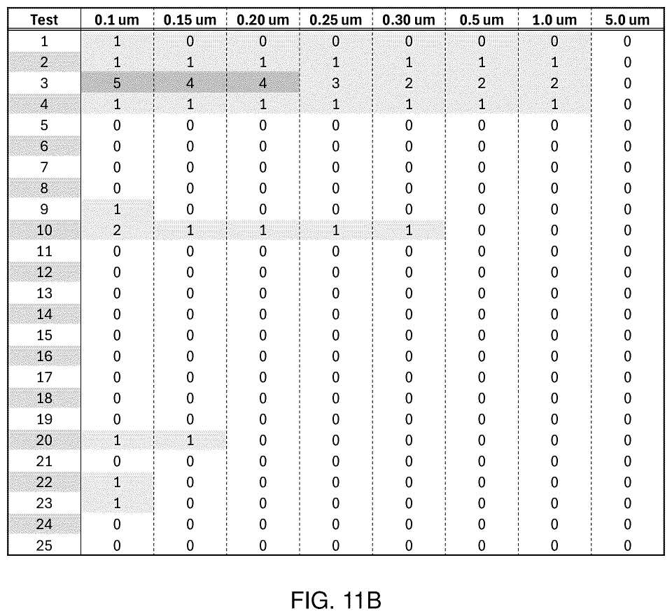

FIGS. 11A and 11B show the results of the particle testing of the Zr 702 tube sample after the 75-hour ozone exposure of the second test. Similar to FIGS. 8A-9B, to count the particles, dry gas was sent through the sample for 5 min and the cumulative number of particles counted over the 5 min time period was recorded. These 5 min cumulative particle counts were then performed 24 times in a row, and the counts for each time period in each particle size range are shown in FIGS. 11A-11B. The cells of the table are shaded reflective of the number of particles.

The Zr tube sample was particle tested for 125 minutes at an air flow of about 1 standard cubic feet per minute (scfm) (about 28 SLM), with the test configured for 25 measurement periods of 5 minutes each, run continuously, i.e., without any delay or hold times in between. FIG. 11A shows that elevated particle counts were observed among the first fourteen 5-minute measurement periods, e.g., during test periods 1, 7, 10 and 14. However, the Zr tubing sample was particle tested a second time, and showed low particles counts indicating that the zirconium tube did not experience measurable corrosion under the humid, oxidizing conditions. FIG. 11B shows the results of the second 125-minute test, and low particles counts at all periods.

There were several sources of particles in the second test that could have contributed to the limited and sporadic observations of particles in FIGS. 11A-11B. The tube samples were handled in room air, without any HEPA filtration to mitigate particle accumulation. The ozone generator itself could also be a source of particles. There was also stainless steel tubing used between the ozone generator and the sample under test. Though not heated to 100° C., the stainless tubing length could have experienced some corrosion during 150 hours (cumulative) of humified ozone exposure. The first 5-minute sampling period could have acted as a gas rinse of the Zr 702 sample, purging it of particles introduced by incidental contamination. Other particle shedding events, e.g., observed during the 7th, 10th, and 14th measurement periods, could similarly have been sporadic shedding events of incidental contamination, for example, due to vibrations from the air pump of the particle counter.

The low particle counts during the last 45 minutes of the first particle test (measurement periods 17-25) and during the last 105 minutes of the second test (measurement periods 5-25) can be considered evidence that the zirconium tube did not experience measurable corrosion under the humid, oxidizing conditions. Not to be limited by theory, zirconium can form a passivating oxide layer of ZrO₂, which can also be renewed in the presence of aqueous media. Such a passivating oxide, in combination with low oxidation rate can explain the resistance to corrosion observed. Oxides of zirconium can range from white to black, with many shades of grey in between, depending on the purity of the Zr alloy and the availability of oxygen when oxidized. For example, the less oxygen available during oxidation at elevated temperature, the darker the oxide.

### CLAUSES

Clause 1. A method for delivering a gas comprising: forming a gas stream comprising vapor hydrogen peroxide using a hydrogen peroxide source of a system; transporting the gas stream from the hydrogen peroxide source to another location of the system using a metal conduit, wherein the metal conduit comprises a metal alloy; and optionally, heating the metal conduit using a heating apparatus coupled to the metal conduit.

Clause 2. The method of clause 1, wherein the metal alloy limits generation of particles formed from the metal alloy when exposed to the vapor hydrogen peroxide.

Clause 3. The method of any of clauses 1-2, wherein the metal alloy limits an amount of decomposition of the vapor hydrogen peroxide.

Clause 4. The method of any of clauses 1-3, wherein the metal alloy generates fewer particles than stainless steel, aluminium, ferrous steel, or titanium when exposed to condensed and evaporated vapor hydrogen peroxide.

Clause 5. The method of any of clauses 1-4, wherein the metal alloy decomposes the vapor hydrogen peroxide less than stainless steel, aluminium, ferrous steel, or titanium does.

Clause 6. The method of any of clauses 1-5, wherein the metal alloy corrodes less than stainless steel, aluminium, ferrous steel, or titanium does when exposed to condensed and evaporated vapor hydrogen peroxide.

Clause 7. The method of any of clauses 1-6, wherein the metal alloy comprises more than 90% zirconium, hafnium, and/or tantalum.

Clause 8. The method of any of clauses 1-7, wherein the metal alloy comprises more than 99% Zr and Hf combined, and less than 5% Hf.

Clause 9. The method of any of clauses 1-8, wherein the metal alloy comprises an unpassivated surface.

Clause 10. The method of any of clauses 1-8, wherein the metal alloy comprises a passivated surface, or an oxidized coating.

Clause 11. The method of any of clauses 1-10, further comprising transporting the gas stream from the hydrogen peroxide source to another location of the system using the metal conduit and one or more delivery components comprising the metal alloy, wherein the delivery components comprise one or more of fittings, valves, flowmeters, filters, pressure controllers, regulators, and fluid sensors, wherein the one or more of fittings, valves, flowmeters, filters, pressure controllers, regulators, and fluid sensors.

Clause 12. The method of any of clauses 1-11, wherein the vapor hydrogen peroxide comprises one or more of a high concentration of hydrogen peroxide, a low concentration of water, and a low concentration of oxygen, and optionally, wherein a concentration of hydrogen peroxide in a liquid process solution in the hydrogen peroxide source is greater than 30%, or greater than 98%, and optionally, wherein a ratio of hydrogen peroxide vapor to water vapor in the gas stream is greater than about 1:10, or greater than about 1:4, or greater than about 1:1, or is greater than about 10:1.

Clause 13. The method of any of clauses 1-12, wherein the gas stream further comprises a carrier gas, or the gas stream is transported from the hydrogen peroxide source to another location of the system using a vacuum.

Clause 14. The method of any of clauses 1-13, further comprising delivering the gas stream to a semiconductor process, wherein the gas stream is substantially free of particles.

Clause 15. The method of any of clauses 1-14, further comprising delivering the gas stream into a process chamber, wherein the gas stream delivered to the process chamber comprises a high concentration of heated hydrogen peroxide vapor, optionally, wherein a ratio of hydrogen peroxide vapor to water vapor in the gas stream delivered to the process chamber is greater than about 1:10, or greater than about 1:4, or greater than about 1:1, or is greater than about 10:1.

Clause 16. A hydrogen peroxide vapor delivery system comprising: a hydrogen peroxide source comprising an outlet configured to output a gas stream comprising vapor hydrogen peroxide; a metal conduit comprising a metal alloy; and optionally, a heating apparatus coupled to the metal conduit configured to heat the metal conduit.

Clause 17. The hydrogen peroxide vapor delivery system of clause 16, wherein the metal alloy limits generation of particles formed from the metal alloy when exposed to the vapor hydrogen peroxide.

Clause 18. The hydrogen peroxide vapor delivery system of any of clauses 16-17, wherein the metal alloy limits an amount of decomposition of the vapor hydrogen peroxide.

Clause 19. The hydrogen peroxide vapor delivery system of any of clauses 16-18, wherein the metal alloy generates fewer particles than stainless steel when exposed to condensed and evaporated vapor hydrogen peroxide.

Clause 20. The hydrogen peroxide vapor delivery system of any of clauses 16-19, wherein the metal alloy decomposes the vapor hydrogen peroxide less than stainless steel does.

Clause 21. The hydrogen peroxide vapor delivery system of any of clauses 16-20, wherein the metal alloy corrodes less than stainless steel does when exposed to condensed and evaporated vapor hydrogen peroxide.

Clause 22. The hydrogen peroxide vapor delivery system of any of clauses 16-21, wherein the metal alloy comprises more than 90% zirconium, hafnium, and/or tantalum.

Clause 23. The hydrogen peroxide vapor delivery system of any of clauses 16-22, wherein the metal alloy comprises more than 99% Zr and Hf combined, and less than 5% Hf.

Clause 24. The hydrogen peroxide vapor delivery system of any of clauses 16-23, wherein the metal alloy comprises an unpassivated surface.

Clause 25. The hydrogen peroxide vapor delivery system of any of clauses 16-23, wherein the metal alloy comprises a passivated surface, or an oxidized coating.

Clause 26. The hydrogen peroxide vapor delivery system of any of clauses 16-25, further comprising transporting the gas stream from the hydrogen peroxide source to other location of the system using the metal conduit and one or more delivery components comprising the metal alloy, wherein the delivery components comprise one or more of fittings, valves, flowmeters, filters, pressure controllers, regulators, and fluid sensors, wherein the one or more of fittings, valves, flowmeters, filters, pressure controllers, regulators, and fluid sensors.

Clause 27. The hydrogen peroxide vapor delivery system of any of clauses 16-26, wherein the vapor hydrogen peroxide comprises one or more of a high concentration of hydrogen peroxide, a low concentration of water, and a low concentration of oxygen, and optionally, wherein a concentration of hydrogen peroxide in a liquid process solution in the hydrogen peroxide source is greater than 30%, or greater than 98%, and optionally, wherein a ratio of hydrogen peroxide vapor to water vapor in the gas stream is greater than about 1:10, or greater than about 1:4, or greater than about 1:1, or is greater than about 10:1.

Clause 28. The hydrogen peroxide vapor delivery system of any of clauses 16-27, wherein the gas stream further comprises a carrier gas, or wherein a vacuum pump is used to transport the gas stream through the outlet.

Clause 29. A method for delivering a gas stream comprising: containing a process solution comprising hydrogen peroxide within a housing comprising a metal alloy, wherein the process solution is either adsorbed onto a substrate or is separated from a head space using a membrane, and wherein the head space is contained within the housing and is separated from the process solution by the substrate or membrane; exposing the head space to a flowing carrier gas or a vacuum, thereby forming a gas stream comprising a gas phase of the process solution; and transporting the gas stream from the housing to another location, using one or more delivery components comprising the metal alloy.

Clause 30. The method of clause 29, wherein the metal alloy limits generation of particles formed from the metal alloy when exposed to the gas phase of the process solution.

Clause 31. The method of any of clauses 29-30, wherein the metal alloy limits an amount of decomposition of vapor hydrogen peroxide.

Clause 32. The method of any of clauses 29-31, wherein the metal alloy generates fewer particles than stainless steel when exposed to condensed and evaporated vapor hydrogen peroxide.

Clause 33. The method of any of clauses 29-32, wherein the metal alloy decomposes vapor hydrogen peroxide less than stainless steel does.

Clause 34. The method of any of clauses 29-33, wherein the metal alloy corrodes less than stainless steel does when exposed to condensed and evaporated vapor hydrogen peroxide.

Clause 35. The method of any of clauses 29-34, wherein the metal alloy comprises more than 90% zirconium, hafnium, and/or tantalum.

Clause 36. The method of any of clauses 29-35, wherein the metal alloy comprises more than 99% Zr and Hf combined, and less than 5% Hf.

Clause 37. The method of any of clauses 29-36, wherein the metal alloy comprises an unpassivated surface.

Clause 38. The method of any of clauses 29-36, wherein the metal alloy comprises a passivated surface, or an oxidized coating.

Clause 39. The method of any of clauses 29-38, wherein the gas phase of the process solution contacts one or more source components or delivery components comprising the metal alloy, wherein the source components or delivery components comprise one or more of heat exchangers, heaters, fittings, valves, flowmeters, filters, pressure controllers, regulators, and fluid sensors.

Clause 40. The method of any of clauses 29-39, wherein the gas phase of the process solution comprises one or more of a high concentration of hydrogen peroxide, a low concentration of water, and a low concentration of oxygen, and optionally, wherein a concentration of hydrogen peroxide in a liquid process solution is greater than 30%, or greater than 98%, and optionally, wherein a ratio of hydrogen peroxide vapor to water vapor in the gas stream is greater than about 1:10, or greater than about 1:4, or greater than about 1:1, or is greater than about 10:1.

Clause 41. The method of any of clauses 29-40, wherein the substrate: is a porous structure with a surface area ranging from about 100 m2/g to 1000 m2/g; or adsorbs w/w hydrogen peroxide greater than 30%, greater than 50%, greater than 70%, greater than 90%, greater than 99%, greater than 100%, greater than 1000%, or greater than 1900% w/w hydrogen peroxide.

Clause 42. A storage device for a process solution comprising: a housing comprising a metal alloy, wherein the housing is configured to contain a process solution comprising hydrogen peroxide; and a substrate or a membrane within the housing, wherein the substrate or membrane is configured to separate the process solution from a head space contained within the housing; wherein the process solution is either adsorbed onto the substrate or is separated from the head space by the membrane, and wherein the housing is configured to allow a carrier gas to flow through the head space, or is configured to allow vacuum to be drawn through the head space, to produce a gas stream comprising a gas phase of the process solution.

Clause 43. The storage device for the process solution of clause 42, wherein the metal alloy limits generation of particles formed from the metal alloy when exposed to vapor hydrogen peroxide.

Clause 44. The storage device for the process solution of any of clauses 42-43, wherein the metal alloy limits an amount of decomposition of vapor hydrogen peroxide.

Clause 45. The storage device for the process solution of any of clauses 42-44, wherein the metal alloy generates fewer particles than stainless steel when exposed to condensed and evaporated vapor hydrogen peroxide.

Clause 46. The storage device for the process solution of any of clauses 42-45, wherein the metal alloy decomposes vapor hydrogen peroxide less than stainless steel does.

Clause 47. The storage device for the process solution of any of clauses 42-46, wherein the metal alloy corrodes less than stainless steel does when exposed to condensed and evaporated vapor hydrogen peroxide.

Clause 48. The storage device for the process solution of any of clauses 42-47, wherein the metal alloy comprises more than 90% zirconium, hafnium, and/or tantalum.

Clause 49. The storage device for the process solution of any of clauses 42-48, wherein the metal alloy comprises more than 99% Zr and Hf combined, and less than 5% Hf.

Clause 50. The storage device for the process solution of any of clauses 42-49, wherein the metal alloy comprises an unpassivated surface.

Clause 51. The storage device for the process solution of any of clauses 42-49, wherein the metal alloy comprises a passivated surface, or an oxidized coating.

Clause 52. The storage device for the process solution of any of clauses 42-51, wherein the storage device further comprises one or more source components or delivery components comprising the metal alloy that are within the housing or coupled to the housing, wherein the source components or delivery components comprise one or more of heat exchangers, heaters, fittings, valves, flowmeters, filters, pressure controllers, regulators, and fluid sensors.

Clause 53. The storage device for the process solution of any of clauses 42-52, wherein the gas phase of the process solution comprises vapor hydrogen peroxide, and one or more of a high concentration of hydrogen peroxide, a low concentration of water, and a low concentration of oxygen, and optionally, wherein a concentration of hydrogen peroxide in a liquid process solution is greater than 30%, or greater than 98%, and optionally, wherein a ratio of hydrogen peroxide vapor to water vapor in the gas stream is greater than about 1:10, or greater than about 1:4, or greater than about 1:1, or is greater than about 10:1.

Clause 54. The storage device for the process solution of any of clauses 42-53, wherein the substrate: is a porous structure with a surface area ranging from about 100 m2/g to 1000 m2/g; or adsorbs over 30% w/w hydrogen peroxide, over 100% w/w hydrogen peroxide, over 1000% w/w hydrogen peroxide, or over 1900% w/w hydrogen peroxide.

Clause 55. The storage device for the process solution of any of clauses 42-54, wherein the substrate or membrane is compatible with the metal alloy and the hydrogen peroxide.

Clause 56. A method for delivering a gas comprising: forming a gas stream comprising an oxidant gas or oxidant vapor using an oxidant gas or oxidant vapor source of a system; transporting the gas stream from the oxidant gas or oxidant vapor source to another location of the system using a metal conduit, wherein the metal conduit comprises a metal alloy; and optionally, heating the metal conduit using a heating apparatus coupled to the metal conduit.

Clause 57. The method of clause 56, wherein the metal alloy limits generation of particles formed from the metal alloy when exposed to the oxidant gas or oxidant vapor.

Clause 58. The method of any of clauses 56-57, wherein the metal alloy limits an amount of decomposition of the oxidant gas or oxidant vapor.

Clause 59. The method of any of clauses 56-58, wherein the metal alloy generates fewer particles than stainless steel, aluminium, ferrous steel, or titanium when exposed to condensed and evaporated oxidant gas or oxidant vapor.

Clause 60. The method of any of clauses 56-59, wherein the metal alloy decomposes the oxidant gas or oxidant vapor less than stainless steel, aluminium, ferrous steel, or titanium does.

Clause 61. The method of any of clauses 56-60, wherein the metal alloy corrodes less than stainless steel, aluminium, ferrous steel, or titanium does when exposed to condensed and evaporated oxidant gas or oxidant vapor.

Clause 62. The method of any of clauses 56-61, wherein the metal alloy comprises more than 90% zirconium, hafnium, and/or tantalum.

Clause 63. The method of any of clauses 56-62, wherein the metal alloy comprises more than 99% Zr and Hf combined, and less than 5% Hf.

Clause 64. The method of any of clauses 56-63, wherein the metal alloy comprises an unpassivated surface.

Clause 65. The method of any of clauses 56-63, wherein the metal alloy comprises a passivated surface, or an oxidized coating.

Clause 66. The method of any of clauses 56-65, further comprising transporting the gas stream from the oxidant gas or oxidant vapor source to another location of the system using the metal conduit and one or more delivery components comprising the metal alloy, wherein the delivery components comprise one or more of fittings, valves, flowmeters, filters, pressure controllers, regulators, and fluid sensors, wherein the one or more of fittings, valves, flowmeters, filters, pressure controllers, regulators, and fluid sensors.

Clause 67. The method of any of clauses 56-66, wherein the gas stream further comprises a carrier gas, or the gas stream is transported from the oxidant gas or oxidant vapor source to another location of the system using a vacuum.

Clause 68. The method of any of clauses 56-67, further comprising delivering the gas stream to a semiconductor process, wherein the gas stream is substantially free of particles.

Clause 69. The method of any of clauses 56-68, wherein the oxidant gas or oxidant vapor comprises one or more of hydrogen peroxide, ozone, oxygen, hypochlorous acid, nitric acid, nitrous oxide, and nitrogen dioxide/dinitrogen tetroxide.

Clause 70. A gas or vapor delivery system comprising: an oxidant gas or oxidant vapor source comprising an outlet configured to output a gas stream comprising an oxidant gas or oxidant vapor; a metal conduit comprising a metal alloy; and optionally, a heating apparatus coupled to the metal conduit configured to heat the metal conduit.

Clause 71. A method for delivering a gas comprising: forming a gas stream comprising an oxidant gas or oxidant vapor using an oxidant gas or oxidant vapor source of a system; transporting the gas stream from the oxidant gas or oxidant vapor source to another location of the system using a metal conduit, wherein the metal conduit comprises a metal alloy, wherein at least 90% of the metal alloy is: zirconium; hafnium; tantalum; a combination of zirconium and hafnium; a combination of zirconium and tantalum; a combination of hafnium and tantalum; or a combination of zirconium, hafnium, and tantalum; and heating the metal conduit using a heating apparatus coupled to the metal conduit.

Clause 72. The method of clause 71, wherein the metal alloy consists of more than 99% Zr and Hf combined, and less than 5% Hf.

Clause 73. The method of any of clauses 71-72, wherein the metal alloy comprises an unpassivated surface.

Clause 74. The method of any of clauses 71-72, wherein the metal alloy comprises a passivated surface, or an oxidized coating.

Clause 75. The method of any of clauses 71-74, wherein the gas stream further comprises a carrier gas or water vapor.

Clause 76. The method of any of clauses 71-74, wherein the gas stream is transported from the oxidant gas or oxidant vapor source to another location of the system using a vacuum.

Clause 77. The method of any of clauses 71-76, wherein the oxidant gas or oxidant vapor source comprises a component comprising the metal alloy.

Clause 78. The method of any of clauses 71-77, further comprising delivering the gas stream to a semiconductor process, wherein the gas stream is substantially free of particles.

Clause 79. The method of any of clauses 71-78, wherein the oxidant gas or oxidant vapor comprises one or more of hydrogen peroxide, ozone, oxygen, hypochlorous acid, nitric acid, nitrous oxide, and nitrogen dioxide/dinitrogen tetroxide.

Clause 80. The method of any of clauses 71-79, wherein, one or more of: the metal alloy limits generation of particles formed from the metal alloy when exposed to the oxidant gas or oxidant vapor; the metal alloy limits an amount of decomposition of the oxidant gas or oxidant vapor; the metal alloy generates fewer particles than are generated by stainless steel, aluminum, ferrous steel, or titanium when exposed to condensed and evaporated oxidant gas or oxidant vapor; the metal alloy decomposes the oxidant gas or oxidant vapor less than stainless steel, aluminum, ferrous steel, or titanium does; and the metal alloy corrodes less than stainless steel, aluminum, ferrous steel, or titanium does when exposed to condensed and evaporated oxidant gas or oxidant vapor.

Clause 81. A gas or vapor delivery system comprising: an oxidant gas or oxidant vapor source comprising an outlet configured to output a gas stream comprising an oxidant gas or oxidant vapor; a metal conduit coupled to the oxidant gas or oxidant vapor source, the metal conduit comprising a metal alloy, wherein at least 90% of the metal alloy is: zirconium; hafnium; tantalum; a combination of zirconium and hafnium; a combination of zirconium and tantalum; a combination of hafnium and tantalum; or a combination of zirconium, hafnium, and tantalum; and a heating apparatus coupled to the metal conduit configured to heat the metal conduit.

Clause 82. The gas or vapor delivery system of clause 81, wherein the metal alloy consists of more than 99% Zr and Hf combined, and less than 5% Hf.

Clause 83. The gas or vapor delivery system of any of clauses 81-82, wherein the metal alloy comprises an unpassivated surface.

Clause 84. The gas or vapor delivery system of any of clauses 81-82, wherein the metal alloy comprises a passivated surface, or an oxidized coating.

Clause 85. The gas or vapor delivery system of any of clauses 81-84, wherein the gas stream further comprises a carrier gas or water vapor.

Clause 86. The gas or vapor delivery system of any of clauses 81-84, wherein the gas stream is transported from the oxidant gas or oxidant vapor source to another location of the system using a vacuum.

Clause 87. The gas or vapor delivery system of any of clauses 81-86, wherein the oxidant gas or oxidant vapor source comprises a component comprising the metal alloy.

Clause 88. The gas or vapor delivery system of any of clauses 81-87, wherein the gas or vapor delivery system is coupled to a semiconductor process, the gas stream is substantially free of particles, and the gas or vapor delivery system is configured to deliver the gas stream to the semiconductor process.

Clause 89. The gas or vapor delivery system of any of clauses 81-88, wherein the oxidant gas or oxidant vapor comprises one or more of hydrogen peroxide, ozone, oxygen, hypochlorous acid, nitric acid, nitrous oxide, and nitrogen dioxide/dinitrogen tetroxide.

Clause 90. The gas or vapor delivery system of any of clauses 81-89, wherein one or more of: the metal alloy limits generation of particles formed from the metal alloy when exposed to the oxidant gas or oxidant vapor; the metal alloy limits an amount of decomposition of the oxidant gas or oxidant vapor; the metal alloy generates fewer particles than are generated by stainless steel, aluminum, ferrous steel, or titanium when exposed to condensed and evaporated oxidant gas or oxidant vapor; the metal alloy decomposes the oxidant gas or oxidant vapor less than stainless steel, aluminum, ferrous steel, or titanium does; and the metal alloy corrodes less than stainless steel, aluminum, ferrous steel, or titanium does when exposed to condensed and evaporated oxidant gas or oxidant vapor.

Reference has been made in detail to embodiments of the disclosed invention, one or more examples of which have been illustrated in the accompanying figures. Each example has been provided by way of explanation of the present technology, not as a limitation of the present technology. In fact, while the specification has been described in detail with respect to specific embodiments of the invention, it will be appreciated that those skilled in the art, upon attaining an understanding of the foregoing, may readily conceive of alterations to, variations of, and equivalents to these embodiments. For instance, features illustrated or described as part of one embodiment may be used with another embodiment to yield a still further embodiment. Thus, it is intended that the present subject matter covers all such modifications and variations within the scope of the appended claims and their equivalents. These and other modifications and variations to the present invention may be practiced by those of ordinary skill in the art, without departing from the scope of the present invention, which is more particularly set forth in the appended claims. Furthermore, those of ordinary skill in the art will appreciate that the foregoing description is by way of example only, and is not intended to limit the invention.

Although the invention has been described with reference to the above example, it will be understood that modifications and variations are encompassed within the scope of the invention. Accordingly, the invention is limited only by the following claims.

1. A method for delivering a gas comprising:
forming a gas stream comprising an oxidant gas or oxidant vapor using an oxidant gas or oxidant vapor source of a system;
transporting the gas stream from the oxidant gas or oxidant vapor source to another location of the system using a metal conduit, wherein the metal conduit is made from a metal alloy, wherein at least 90% of the metal alloy is: zirconium; a combination of zirconium and hafnium; a combination of zirconium and tantalum; or a combination of zirconium, hafnium, and tantalum; and
heating the metal conduit using a heating apparatus coupled to the metal conduit.

2. The method of claim 1, wherein the metal alloy consists of more than 99% Zr and Hf combined, and less than 5% Hf.

3. The method of claim 1, wherein the metal alloy comprises an unpassivated surface.

4. The method of claim 1, wherein the metal alloy comprises a passivated surface, or an oxidized coating.

5. The method of claim 1, wherein the gas stream further comprises a carrier gas.

6. The method of claim 1, wherein the gas stream further comprises water vapor.

7. The method of claim 1, wherein the gas stream is transported from the oxidant gas or oxidant vapor source to another location of the system using a vacuum.

8. The method of claim 1, wherein the oxidant gas or oxidant vapor source comprises a component comprising the metal alloy.

9. The method of claim 1, further comprising delivering the gas stream to a semiconductor process, wherein the gas stream is substantially free of particles.

10. The method of claim 1, wherein the oxidant gas or oxidant vapor comprises one or more of hydrogen peroxide, ozone, oxygen, hypochlorous acid, nitric acid, nitrous oxide, and nitrogen dioxide/dinitrogen tetroxide.

11. The method of claim 1, wherein, one or more of:
the metal alloy limits generation of particles formed from the metal alloy when exposed to the oxidant gas or oxidant vapor;
the metal alloy limits an amount of decomposition of the oxidant gas or oxidant vapor;
the metal alloy generates fewer particles than are generated by stainless steel, aluminum, ferrous steel, or titanium when exposed to condensed and evaporated oxidant gas or oxidant vapor;
the metal alloy decomposes the oxidant gas or oxidant vapor less than stainless steel, aluminum, ferrous steel, or titanium does; and
the metal alloy corrodes less than stainless steel, aluminum, ferrous steel, or titanium does when exposed to condensed and evaporated oxidant gas or oxidant vapor.

12. A gas or vapor delivery system comprising:
an oxidant gas or oxidant vapor source comprising an outlet configured to output a gas stream comprising an oxidant gas or oxidant vapor;
a metal conduit coupled to the oxidant gas or oxidant vapor source, wherein the metal conduit is made from a metal alloy, wherein at least 90% of the metal alloy is: zirconium; a combination of zirconium and hafnium; a combination of zirconium and tantalum; or a combination of zirconium, hafnium, and tantalum; and
a heating apparatus coupled to the metal conduit configured to heat the metal conduit.

13. The gas or vapor delivery system of claim 12, wherein the metal alloy consists of more than 99% Zr and Hf combined, and less than 5% Hf.

14. The gas or vapor delivery system of claim 12, wherein the metal alloy comprises an unpassivated surface.

15. The gas or vapor delivery system of claim 12, wherein the metal alloy comprises a passivated surface, or an oxidized coating.

16. The gas or vapor delivery system of claim 12, wherein the gas stream further comprises a carrier gas.

17. The gas or vapor delivery system of claim 12, wherein the gas stream further comprises water vapor.

18. The gas or vapor delivery system of claim 12, wherein the gas stream is transported from the oxidant gas or oxidant vapor source to another location of the system using a vacuum.

19. The gas or vapor delivery system of claim 12, wherein the oxidant gas or oxidant vapor source comprises a component comprising the metal alloy.

20. The gas or vapor delivery system of claim 12, wherein the gas or vapor delivery system is coupled to a semiconductor process, the gas stream is substantially free of particles, and the gas or vapor delivery system is configured to deliver the gas stream to the semiconductor process.

21. The gas or vapor delivery system of claim 12, wherein the oxidant gas or oxidant vapor comprises one or more of hydrogen peroxide, ozone, oxygen, hypochlorous acid, nitric acid, nitrous oxide, and nitrogen dioxide/dinitrogen tetroxide.

22. The gas or vapor delivery system of claim 12, wherein one or more of:
the metal alloy limits generation of particles formed from the metal alloy when exposed to the oxidant gas or oxidant vapor;
the metal alloy limits an amount of decomposition of the oxidant gas or oxidant vapor;
the metal alloy generates fewer particles than are generated by stainless steel, aluminum, ferrous steel, or titanium when exposed to condensed and evaporated oxidant gas or oxidant vapor;
the metal alloy decomposes the oxidant gas or oxidant vapor less than stainless steel, aluminum, ferrous steel, or titanium does; and
the metal alloy corrodes less than stainless steel, aluminum, ferrous steel, or titanium does when exposed to condensed and evaporated oxidant gas or oxidant vapor.
